(19) United States
(12) Patent Application Publication
(10) Pub. No.: US 2022/0181353 A1
(43) Pub. Date: Jun. 9, 2022

(54) SEMICONDUCTOR MEMORY DEVICE AND MANUFACTURING METHOD THEREOF

(71) Applicant: Postech Research and Business Development Foundation, Pohang-si (KR)

(72) Inventors: Jang-Sik LEE, Pohang-si (KR); Ik-Jyae KIM, Seoul (KR); Min-Kyu KIM, Pohang-si (KR)

(73) Assignee: Postech Research and Business Development Foundation, Pohang-si (KR)

(21) Appl. No.: 17/530,014

(22) Filed: Nov. 18, 2021

(30) Foreign Application Priority Data
Dec. 4, 2020 (KR) 10-2020-0168022

(51) Int. Cl. H01L 27/11597; H01L 21/02; H01L 29/24; H01L 21/28; H01L 29/51

(52) U.S. Cl. CPC H01L 27/11597; H01L 21/02565; H01L 29/516; H01L 29/40111; H01L 29/24

(57) ABSTRACT

A method for manufacturing a semiconductor memory device according to the inventive concept includes forming an electrode structure by alternately stacking insulation layers and electrodes on a substrate, forming a channel hole penetrating the electrode structure, and forming a vertical channel structure filling the channel hole, wherein the forming the vertical channel structure includes forming a ferroelectric layer on an inner sidewall of the channel hole, forming an oxide semiconductor layer on the ferroelectric layer, and performing an annealing process on the oxide semiconductor layer.

### CROSS-REFERENCE TO RELATED APPLICATIONS

This U.S. non-provisional patent application claims priority under 35 U.S.C. § 119 of Korean Patent Application No. 10-2020-0168022, filed on Dec. 4, 2020, the entire contents of which are hereby incorporated by reference.

### BACKGROUND

The present disclosure herein relates to a semiconductor memory device and a manufacturing method thereof, and more particularly, to a semiconductor memory device having improved electrical characteristics and a manufacturing method thereof.

In electronic industry, semiconductor devices are regarded as important elements due to characteristics such as small size, multiple functions, and/or low manufacturing cost. Semiconductor devices may be classified into semiconductor memory devices for storing logical data, semiconductor logic devices for processing operations on logical data, and hybrid semiconductor devices including a memory element and logic element. As the electronic industry highly develops, requirements pertaining to characteristics of semiconductor devices increase. For example, semiconductor devices are required to have higher reliability, higher speed, and/or more functions. In order to satisfy such required characteristics, semiconductor devices have more complicated structures and are more highly integrated.

### SUMMARY

The present disclosure provides a semiconductor memory device having improved electrical characteristics and a manufacturing method thereof.

An embodiment of the inventive concept provides a method for manufacturing a semiconductor memory device, including forming an electrode structure by alternately stacking insulation layers and electrodes on a substrate, forming a channel hole penetrating the electrode structure, and forming a vertical channel structure filling the channel hole, wherein the forming the vertical channel structure includes forming a ferroelectric layer on an inner sidewall of the channel hole, forming an oxide semiconductor layer on the ferroelectric layer, and performing an annealing process on the oxide semiconductor layer.

In an embodiment of the inventive concept, a method for manufacturing a semiconductor memory device includes forming a ferroelectric layer on an electrode, forming an oxide semiconductor layer on the ferroelectric layer, performing an annealing process on the oxide semiconductor layer, and forming a source electrode and a drain electrode on the oxide semiconductor layer, wherein the ferroelectric layer and the oxide semiconductor layer physically contact each other.

In an embodiment of the inventive concept, a semiconductor memory device includes a substrate, an electrode structure including a plurality of electrodes stacked on the substrate, and a vertical channel structure penetrating the electrode structure, wherein the vertical channel structure includes an oxide semiconductor layer extending vertically, and a ferroelectric layer between the plurality of electrodes and the oxide semiconductor layer, wherein the ferroelectric layer and the oxide semiconductor layer physically contact each other.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a semiconductor memory device according to embodiments of the inventive concept;

FIG. 2 is a cross-sectional view illustrating a method for manufacturing a semiconductor memory device according to embodiments of the inventive concept;

FIG. 3 is a cross-sectional view illustrating a method for manufacturing a semiconductor memory device according to a comparative example of the inventive concept;

FIG. 4 is a graph illustrating hysteresis curves of a ferroelectric layer according to whether or not an oxide semiconductor layer and an annealing process are used;

FIG. 5A is a graph illustrating hysteresis curves of a ferroelectric layer of a semiconductor memory device according to embodiments of the inventive concept;

FIG. 5B is a graph illustrating hysteresis curves of a ferroelectric layer of a semiconductor memory device according to a comparative example of the inventive concept;

FIG. 6A is a graph illustrating a polarization characteristic when a rectangular bipolar pulse (±6 V, 4 μs) is applied to a semiconductor memory device according to embodiments of the inventive concept;

FIG. 6B is a graph illustrating hysteresis curves before and after 10⁵ cycles of a pulse are applied to a semiconductor memory device according to embodiments of the inventive concept;

FIG. 7A is a graph illustrating a polarization characteristic when a rectangular bipolar pulse is applied to a semiconductor memory device according to a comparative example of the inventive concept;

FIG. 7B is a graph illustrating hysteresis curves before and after 10⁵ cycles of a pulse are applied to a semiconductor memory device according to a comparative example of the inventive concept;

FIG. 8A is a graph illustrating a polarization characteristic when a rectangular bipolar pulse is applied, after occurrence of a wake-up effect, to a semiconductor memory device according to a comparative example of the inventive concept;

FIG. 8B is a graph illustrating hysteresis curves before and after 10⁵ cycles of a pulse are applied, after occurrence of a wake-up effect, to a semiconductor memory device according to a comparative example of the inventive concept;

FIGS. 9A and 9B are graphs illustrating polarization switching characteristics according to an amplitude and width of a pulse applied to a semiconductor memory device according to embodiments of the inventive concept;

FIG. 9C is a graph illustrating a polarization switching characteristic according to a pulse applied to a semiconductor memory device according to embodiments of the inventive concept under a displacement current limit condition;

FIG. 9D is a graph illustrating a polarization switching characteristic of a semiconductor memory device according to embodiments of the inventive concept under a displacement current limit condition;

FIG. 10A is a graph illustrating transfer curves according to a voltage (gate voltage, V_{G}) applied to the electrode EL and a voltage (drain voltage, \T_{DS}) applied to the drain electrode DEL in a semiconductor memory device according to embodiments of the inventive concept;

FIG. 10B is a graph illustrating a relationship between a drain current I_{DS} and a gate voltage V_{G} according to a polarization state of the ferroelectric layer FE of a semiconductor memory device according to embodiments of the inventive concept;

FIG. 10C is a graph illustrating a threshold voltage Vₜh according to programmed and erased states of a semiconductor memory device according to embodiments of the inventive concept;

FIG. 11 is a cross-sectional view of a semiconductor memory device according to embodiments of the inventive concept;

FIGS. 12A to 12F are cross-sectional views illustrating a method for manufacturing a semiconductor memory device according to embodiments of the inventive concept;

FIG. 13 is a cross-sectional view of a semiconductor memory device according to embodiments of the inventive concept;

FIGS. 14A and 14B are cross-sectional views illustrating a method for manufacturing a semiconductor memory device according to embodiments of the inventive concept;

FIG. 15 is a cross-sectional view of a semiconductor memory device according to embodiments of the inventive concept;

FIG. 16 is a schematic perspective view of a semiconductor memory device according to embodiments of the inventive concept;

FIG. 17 is a schematic plan view of a semiconductor memory device according to embodiments of the inventive concept;

FIG. 18 is a plan view for describing a semiconductor memory device according to embodiments of the inventive concept;

FIGS. 19A and 19B are cross-sectional views of the semiconductor memory device taken along line I-I′ and line II-II′ of FIG. 18, respectively;

FIGS. 20A, 21A, 22A, 23A, 24A, 25A, and 26A, which are for describing a method for manufacturing a semiconductor memory device according to embodiments of the inventive concept, are cross-sectional views of the semiconductor memory device taken along line I-I′ of FIG. 18;

FIGS. 20B, 21B, 22B, 23B, 24B, 25B, and 26B, which are for describing the method for manufacturing the semiconductor memory device according to embodiments of the inventive concept, are cross-sectional views of the semiconductor memory device taken along line II-II′ of FIG. 18;

FIGS. 27A and 28A, which are for describing a method for manufacturing a semiconductor memory device according to embodiments of the inventive concept, are cross-sectional views of the semiconductor memory device taken along line I-I′ of FIG. 18; and

FIGS. 27B and 28B, which are for describing a method for manufacturing a semiconductor memory device according to embodiments of the inventive concept, are cross-sectional views of the semiconductor memory device taken along line II-II′ of FIG. 18.

### DETAILED DESCRIPTION

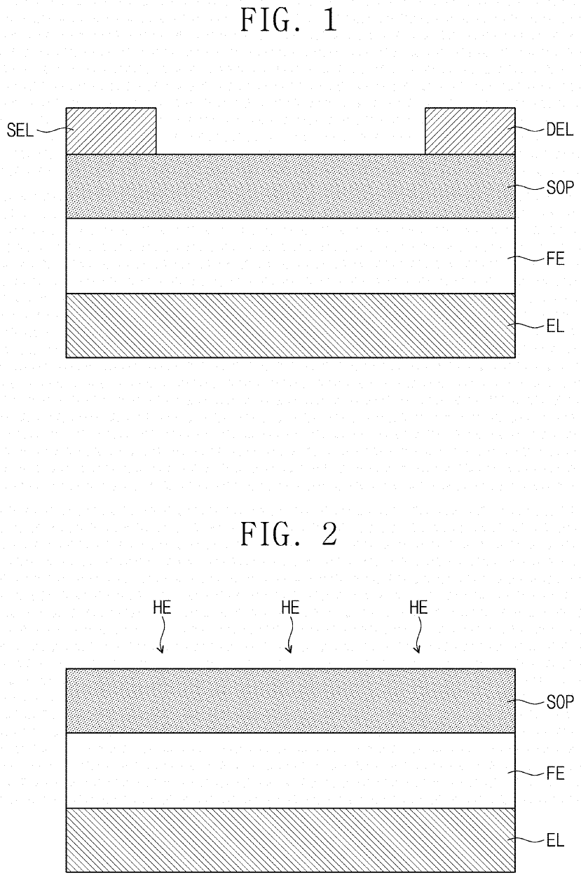

FIG. 1 is a cross-sectional view of a semiconductor memory device according to embodiments of the inventive concept.

Referring to FIG. 1, a ferroelectric layer FE may be provided on an electrode EL. The electrode EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum).

The ferroelectric layer FE may be conformally provided on the electrode EL. For example, the ferroelectric layer FE may include a hafnium (Hf) oxide, and may further include at least one of zirconium (Zr), silicon (Si), aluminum (Al), gadolinium (Gd), or yttrium (Y). A ferroelectric phase of the ferroelectric layer FE may be induced by the oxide semiconductor layer SOP described below.

The oxide semiconductor layer SOP may include an oxide semiconductor material. For example, the oxide semiconductor layer SOP may include at least one of In₂O₃, ZnO, InZnO (IZO), InGaO (IGO), ZnSnO (ZTO), Al ZnO (AZO), GaZnO (GZO), InGaZnO (IGZO), InZnSnO (IZTO), or HfInZnO(HIZO). The oxide semiconductor layer SOP may be used as a channel of transistors. A thermal expansion coefficient of the oxide semiconductor layer SOP may be different from a thermal expansion coefficient of the ferroelectric layer FE. The oxide semiconductor layer SOP and the ferroelectric layer FE may not have an additional interfacial layer therebetween, and thus may physically contact each other. Since the additional interfacial layer is not formed by using the oxide semiconductor layer SOP, the memory device may exhibit characteristics of low operational voltage and improved reliability and memory window compared to a typical memory device. The oxide semiconductor layer SOP may be conformally formed on the ferroelectric layer FE.

A source electrode SEL and a drain electrode DEL may be provided on the oxide semiconductor layer SOP. The source electrode SEL and the drain electrode DEL may extend parallel in one direction and may be spaced apart from each other. For example, the source electrode SEL and the drain electrode DEL may include a metal material such as aluminum (Al), tungsten (W), molybdenum (Mo), etc.

The semiconductor memory device according to embodiments of the inventive concept may be a two-dimensional NAND flash memory device. An interfacial layer may be prevented from being formed between a channel and a ferroelectric material by using the oxide semiconductor layer SOP rather than a polysilicon layer as a channel. As a result, electrical characteristics of the semiconductor memory device may be improved.

FIG. 2 is a cross-sectional view illustrating a method for manufacturing a semiconductor memory device according to embodiments of the inventive concept.

Referring to FIG. 2, the ferroelectric layer FE may be formed on the electrode EL. The ferroelectric layer FE may be conformally formed on the electrode EL using an atomic layer deposition (ALD) process. The electrode EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum), and the ferroelectric layer FE may include a hafnium (Hf) oxide, and may further include at least one of zirconium (Zr), silicon (Si), aluminum (Al), gadolinium (Gd), or yttrium (Y).

The oxide semiconductor layer SOP may be formed on the ferroelectric layer FE. The oxide semiconductor layer SOP may be conformally formed on the ferroelectric layer FE using an atomic layer deposition (ALD) process. The oxide semiconductor layer SOP may include, for example, at least one of In₂O₃, ZnO, IZO, IGO, ZTO, AZO, GZO, IGZO, IZTO, or HIZO. A thermal expansion coefficient of the oxide semiconductor layer SOP may be different from a thermal expansion coefficient of the ferroelectric layer FE.

An annealing process HE may be performed on the oxide semiconductor layer SOP. The annealing process HE may be performed for about 1 second to about 600 seconds at a temperature of about 280° C. to about 1000° C. Preferably, the annealing process HE may be performed at a temperature of about 400° C. to about 600° C. A ferroelectric phase of the ferroelectric layer FE may be induced by the annealing process HE performed on the oxide semiconductor layer SOP. That is, the oxide semiconductor layer SOP may function as a capping layer for inducing the ferroelectric phase of the ferroelectric layer FE.

The oxide semiconductor layer SOP may have an electron density of about 10¹⁵ cm⁻³ to about 10²¹ cm⁻³. The electron density of the oxide semiconductor layer SOP may be adjusted according to a polarization magnitude of the ferroelectric layer FE and a thickness of the oxide semiconductor layer SOP. Furthermore, the electron density may be adjusted by temperature of the atomic layer deposition (ALD) process for depositing the oxide semiconductor layer SOP.

Referring back to FIG. 1, the source electrode SEL and the drain electrode DEL may be formed on the oxide semiconductor layer SOP. The source electrode SEL and the drain electrode DEL may include a metal material such as aluminum (Al), tungsten (W), molybdenum (Mo), etc.

The oxide semiconductor layer SOP may remain without being removed after inducing the ferroelectric phase of the ferroelectric layer FE. That is, the oxide semiconductor layer SOP may function as a capping layer and channel of the semiconductor memory device.

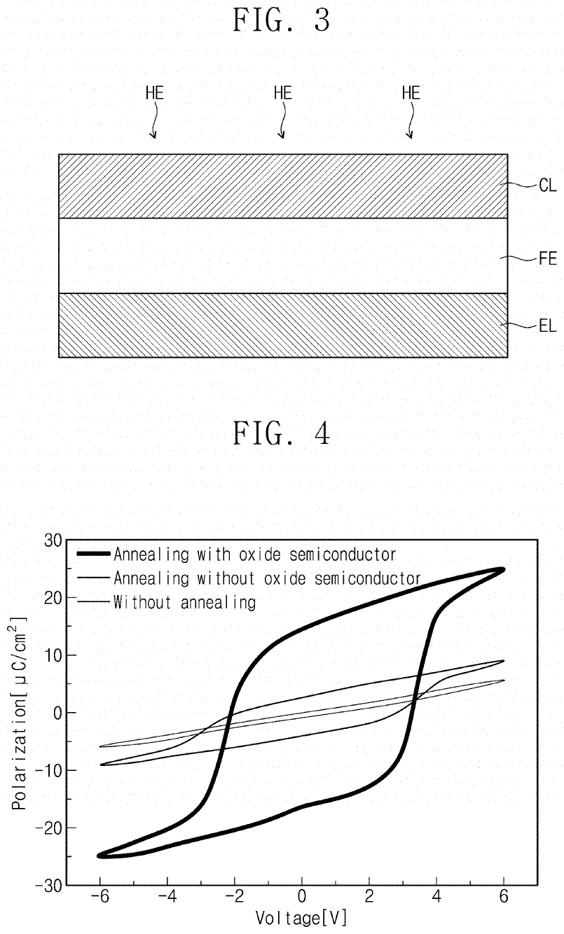

FIG. 3 is a cross-sectional view illustrating a method for manufacturing a semiconductor memory device according to a comparative example of the inventive concept. Hereinafter, descriptions overlapping with the above descriptions will not be provided, and differences will be described in detail.

Referring to FIG. 3, a capping layer CL may be formed on the ferroelectric layer FE. The capping layer CL may be a layer formed to induce the ferroelectric phase of the ferroelectric layer FE. A thermal expansion coefficient of the capping layer CL may be greater than the thermal expansion coefficient of the oxide semiconductor layer SOP of FIG. 2. The capping layer CL may include the same material as the electrode EL. For example, the capping layer CL may include a metal nitride or metal material such as titanium nitride, tantalum nitride, tantalum, platinum, or the like.

The annealing process HE may be performed on the capping layer CL after the capping layer CL is formed. The ferroelectric phase of the ferroelectric layer FE may be induced by the annealing process HE performed on the capping layer CL. As described below, characteristics of a memory device may deteriorate when the process of FIG. 3 is used in comparison with the process of FIG. 2.

Referring back to FIG. 1, the capping layer CL may be removed by an etching process. The etching process may cause occurrence of a defect in a surface of the ferroelectric layer FE. As a result, characteristics of the memory device may deteriorate. The oxide semiconductor layer SOP, the source electrode SEL, and the drain electrode DEL may be sequentially formed on the ferroelectric layer FE.

FIG. 4 is a graph illustrating hysteresis curves of a ferroelectric layer according to whether or not an oxide semiconductor layer and an annealing process are used.

Referring to FIG. 4, the ferroelectric phase of the ferroelectric layer is not induced when the annealing process are not performed. A stable ferroelectric phase is induced when the annealing process is performed after forming the oxide semiconductor layer on the ferroelectric layer. Induction of the ferroelectric phase deteriorates when only the annealing process is performed without forming the oxide semiconductor layer compared to when the oxide semiconductor layer is formed.

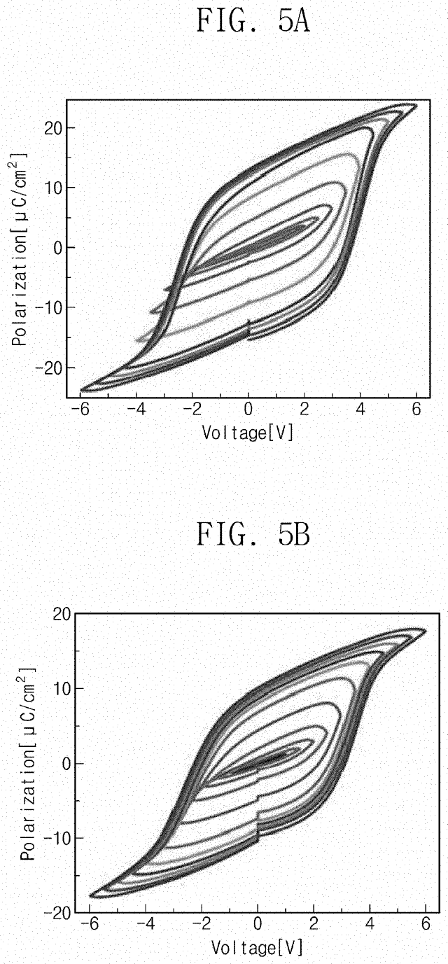

FIG. 5A is a graph illustrating hysteresis curves of a ferroelectric layer of a semiconductor memory device according to embodiments of the inventive concept. FIG. 5B is a graph illustrating hysteresis curves of a ferroelectric layer of a semiconductor memory device according to a comparative example of the inventive concept.

Referring to FIGS. 5A and 5B, the ferroelectric layer of the semiconductor memory device according to embodiments of the inventive concept exhibits a more improved polarization characteristic that the ferroelectric layer of the semiconductor memory device according to a comparative example of the inventive concept. This is because an additional interfacial layer is not formed on the ferroelectric layer due to usage of the oxide semiconductor layer, and occurrence of a surface defect of the ferroelectric layer reduces since a process of etching the capping layer is skipped. Furthermore, a ferroelectric phase inducing characteristic is also improved since the thermal expansion coefficient of the oxide semiconductor layer is less than that of the capping layer.

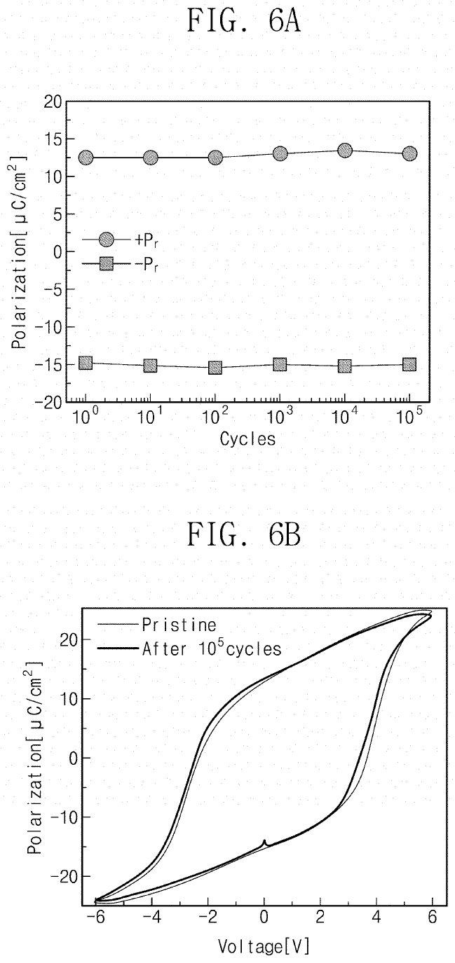

FIG. 6A is a graph illustrating a polarization characteristic after a rectangular bipolar pulse (±6 V, 4 μs) is applied to a semiconductor memory device according to embodiments of the inventive concept. FIG. 6B is a graph illustrating hysteresis curves before and after 10⁵ cycles of a pulse are applied to a semiconductor memory device according to embodiments of the inventive concept.

Referring to FIGS. 6A and 6B, it may be confirmed that there is almost no change in the polarization characteristic even when a pulse is repeatedly applied.

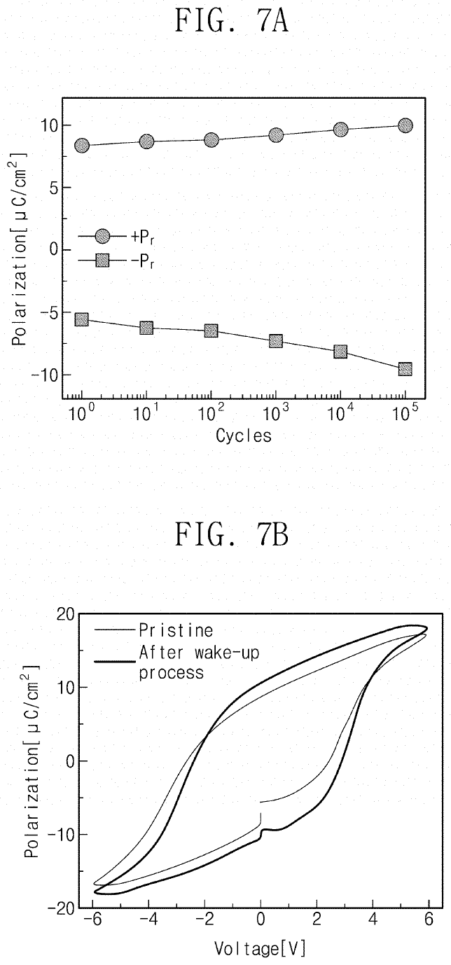

FIG. 7A is a graph illustrating a polarization characteristic when a rectangular bipolar pulse is applied to a semiconductor memory device according to a comparative example of the inventive concept. FIG. 7B is a graph illustrating hysteresis curves before and after 10⁵ cycles of a pulse are applied to a semiconductor memory device according to a comparative example of the inventive concept.

Referring to FIGS. 7A and 7B, a wake-up effect occurs, in which remnant polarization increases due to repeated pulse application, unlike the cases of FIGS. 6A and 6B.

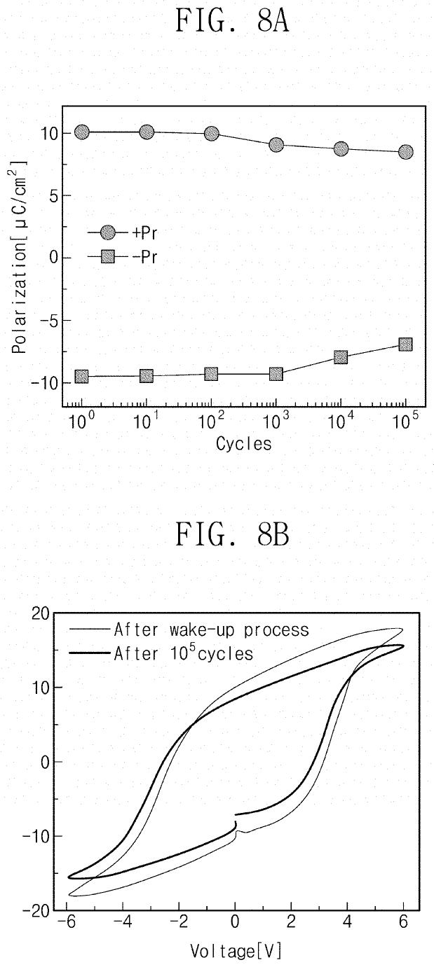

FIG. 8A is a graph illustrating a polarization characteristic after a rectangular bipolar pulse is applied, after occurrence of a wake-up effect, to a semiconductor memory device according to a comparative example of the inventive concept. FIG. 8B is a graph illustrating hysteresis curves before and after 10⁵ cycles of a pulse are applied, after occurrence of a wake-up effect, to a semiconductor memory device according to a comparative example of the inventive concept.

Referring to FIGS. 8A and 8B, it may be confirmed that the polarization characteristic deteriorates when a pulse is repeatedly applied. That is, the semiconductor memory device according to embodiments of the inventive concept has more improved durability than the semiconductor memory device according to a comparative example of the inventive concept.

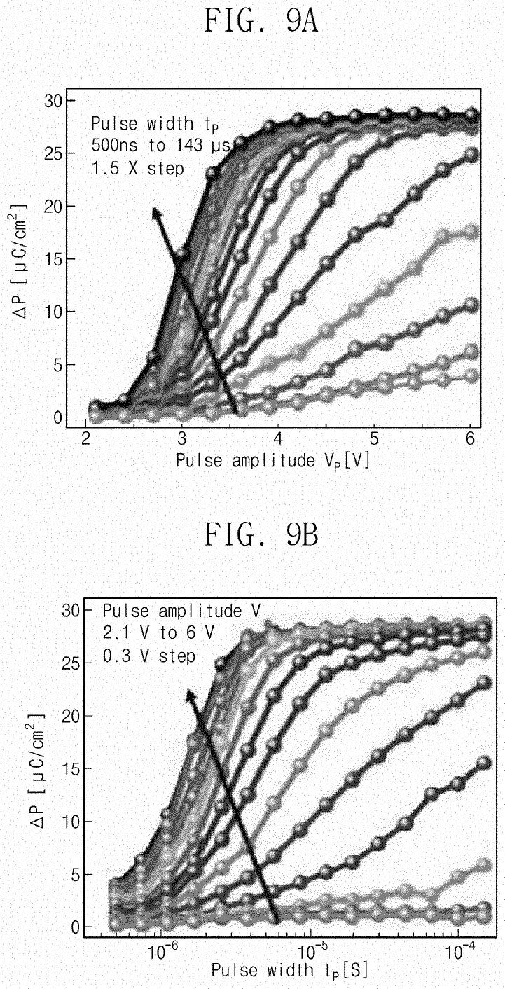

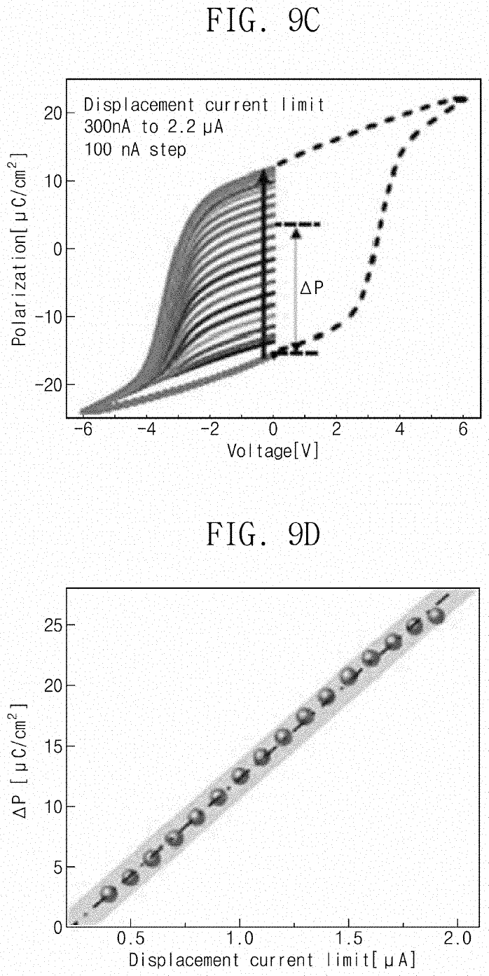

FIGS. 9A and 9B are graphs illustrating polarization switching characteristics according to an amplitude and width of a pulse applied to a semiconductor memory device according to embodiments of the inventive concept.

Referring to FIGS. 9A and 9B, the polarization switching characteristic of a ferroelectric layer may be adjusted by controlling the amplitude and width of the applied pulse. (Measurement was performed by increasing the pulse width tₚ by 1.5 times each time from 500 nm to 143 μs and increasing the amplitude Vₚ by 0.3 V each time from 2.1 V to 6 V)

FIG. 9C is a graph illustrating a polarization switching characteristic according to a pulse applied to a semiconductor memory device according to embodiments of the inventive concept under a displacement current limit condition. FIG. 9D is a graph illustrating a polarization switching characteristic of a semiconductor memory device according to embodiments of the inventive concept under a displacement current limit condition.

Referring to FIGS. 9C and 9D, it may be confirmed that the polarization switching characteristic and the displacement current limit have a proportional relationship (measurement was performed by increasing the displacement current limit by 100 nA each time from 300 nA to 2.2 μA). That is, it may be confirmed that the polarization characteristic linearly increases as the displacement current limit increases.

As a result, the semiconductor memory device according to embodiments of the inventive concept may store multi-level data by adjusting the polarization switching characteristic. This characteristic is suitable for application to a neuromorphic device.

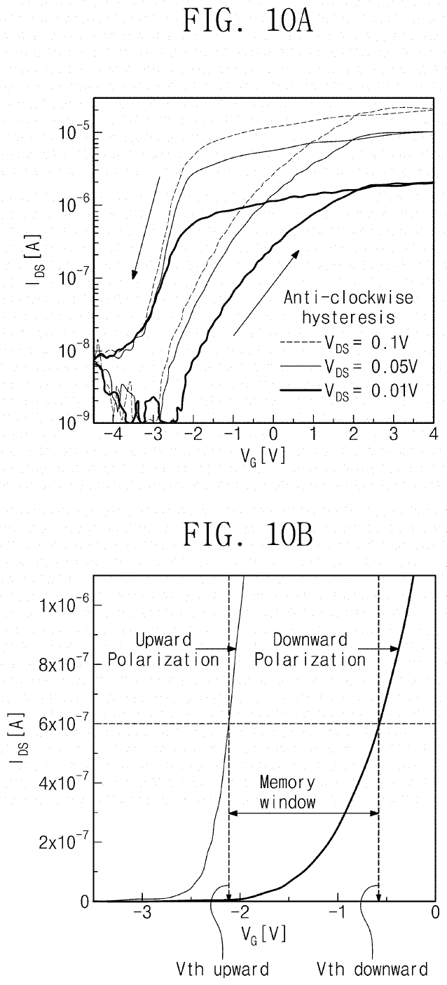

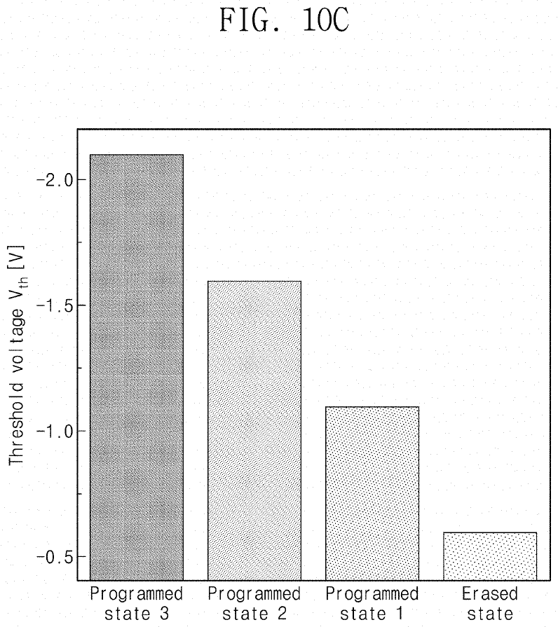

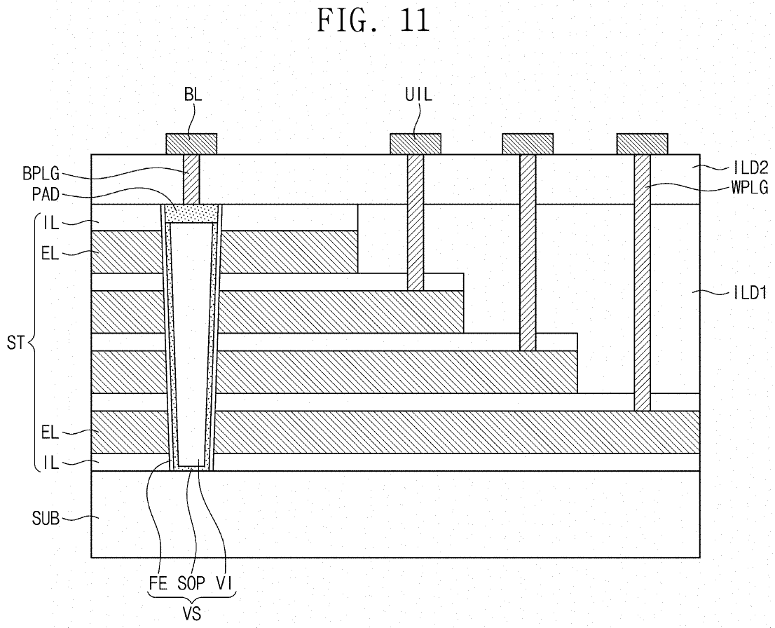

FIG. 10A is a graph illustrating transfer curves according to a voltage (gate voltage, V_{G}) applied to the electrode EL and a voltage (drain voltage, V_{DS}) applied to the drain electrode DEL in a semiconductor memory device according to embodiments of the inventive concept. FIG. 10B is a graph illustrating a relationship between a drain current I_{DS} and a gate voltage V_{G} according to a polarization state of the ferroelectric layer FE of a semiconductor memory device according to embodiments of the inventive concept. FIG. 10C is a graph illustrating a threshold voltage Vₜₕ at programmed and erased states of a semiconductor memory device according to embodiments of the inventive concept.

Referring to FIG. 10A, an anti-clockwise hysteresis curve according to a polarization switching phenomenon of a ferroelectric layer may be recognized. Referring to FIG. 10B, it may be confirmed that the threshold voltage Vₜₕ varies according to a polarization state (upward or downward polarization) of a ferroelectric layer. Referring to FIG. 10C, the threshold voltage varies according to an amplitude of an applied program pulse, thus making it possible to store multi-level data. As a result, a semiconductor memory device according to embodiments of the inventive concept is suitable for application to the fields of neuromorphic devices and the like.

FIG. 11 is a cross-sectional view of a semiconductor memory device according to embodiments of the inventive concept.

Referring to FIG. 11, in the semiconductor memory device according to embodiments of the inventive concept, an electrode structure ST may be provided on a substrate SUB. A first interlayer dielectric ILD1 and a second interlayer dielectric ILD2 may be provided on the substrate SUB. An upper surface of the first interlayer dielectric ILD1 and an upper surface of the electrode structure ST may be coplanar. The substrate SUB may be a monocrystalline epitaxial layer grown on a silicon substrate, silicon-germanium substrate, germanium substrate, or monocrystalline silicon substrate.

The electrode structure ST may include vertically stacked electrodes EL on the substrate SUB. The electrode structure ST may further include insulation layers IL separating the stacked electrodes EL from each other. The insulation layers IL and the electrodes EL of the electrode structure ST may be alternately stacked.

The electrode structure ST may have a stepped structure. The stepped structure of the electrode structure ST may have a height that decreases in a direction from bit lines BL to upper wirings UIL, which are described below.

A lowermost electrode EL among the electrodes EL of the electrode structure ST may be a lower selection line. An uppermost electrode EL among the electrodes EL of the electrode structure ST may be an upper selection line. The electrodes EL except for the lower selection line and the upper selection line may be word lines.

The electrodes EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum). The insulation layers IL may include a silicon oxide film.

A vertical channel structure VS penetrating the electrode structure ST may be provided. For example, a diameter of the vertical channel structure VS may gradually reduce towards the substrate SUB.

The vertical channel structure VS may include the ferroelectric layer FE, the oxide semiconductor layer SOP, and a pillar VI. The oxide semiconductor layer SOP may be disposed between the ferroelectric layer FE and the pillar VI.

The pillar VI may have a cylindrical shape. The pillar VI may vertically extend on the oxide semiconductor layer SOP. For example, the pillar VI may include a silicon oxide film.

The oxide semiconductor layer SOP may be vertically extend, covering a surface of the pillar VI. The ferroelectric layer FE may vertically extend, covering an outer surface of the oxide semiconductor layer SOP. The ferroelectric layer FE may be disposed between the electrode structure ST and the oxide semiconductor layer SOP.

The ferroelectric layer FE may include a hafnium (Hf) oxide, and may further include at least one of zirconium (Zr), silicon (Si), aluminum (Al), gadolinium (Gd), or yttrium (Y). The ferroelectric phase of the ferroelectric layer FE may be induced by the oxide semiconductor layer SOP.

The oxide semiconductor layer SOP may include an oxide semiconductor material. For example, the oxide semiconductor layer SOP may include at least one of In₂O₃, ZnO, IZO, IGO, ZTO, AZO, GZO, IGZO, IZTO, or HIZO. The oxide semiconductor layer SOP may be used as a channel of transistors constituting a NAND cell string. A thermal expansion coefficient of the oxide semiconductor layer SOP may be different from a thermal expansion coefficient of the ferroelectric layer FE. The oxide semiconductor layer SOP and the ferroelectric layer FE may not have an additional interfacial layer therebetween, and thus may physically contact each other. The oxide semiconductor layer SOP may have an electron density of about 10¹⁵ cm⁻³ to about 10²¹ cm⁻³. The electron density of the oxide semiconductor layer SOP may be adjusted according to a polarization magnitude of the ferroelectric layer FE and a thickness of the oxide semiconductor layer SOP.

A conductive pad PAD may be provided in the vertical channel structure VS. The conductive pad PAD may cover an upper surface of the oxide semiconductor layer SOP and an upper surface of the pillar VI. A sidewall of the conductive pad PAD may contact the ferroelectric layer FE. The conductive pad PAD may include a semiconductor material and/or conductive material doped with impurities. A bit line contact plug BPLG may be electrically connected to the oxide semiconductor layer SOP through the conductive pad PAD. An upper surface of the conductive pad PAD and an upper surface of the ferroelectric layer FE may be substantially coplanar. The ferroelectric layer FE may be disposed between the conductive pad PAD and the electrode structure ST.

The oxide semiconductor layer SOP may contact an upper surface of the substrate SUB. The substrate SUB may function as a source of memory cells. A common source voltage may be applied to the substrate SUB. Namely, an upper portion of the substrate SUB may have a conductive type by being doped with impurities, and may contact the oxide semiconductor layer SOP so as to function as a source of memory cells. The upper portion of the substrate SUB may include a semiconductor material (e.g., at least one of silicon (Si), germanium (Ge), silicon germanium (SiGe), gallium arsenide (GaAs), indium gallium arsenide (InGaAs), aluminum gallium arsenide (AlGaAs), or mixtures thereof). For example, the upper portion of the substrate SUB may include a polysilicon layer doped with impurities and having an N type.

The semiconductor memory device according to embodiments of the inventive concept may be a three-dimensional NAND flash memory device. NAND cell strings may be integrated in the electrode structure ST on the substrate SUB. That is, the electrode structure ST and the vertical channel structure VS penetrating therethrough may constitute memory cells three-dimensionally arranged on the substrate SUB. The electrodes EL of the electrode structure ST may be used as gate electrodes of transistors.

The second interlayer dielectric ILD2 may be provided on the first interlayer dielectric ILD1. The bit line contact plugs BPLG may penetrate the second interlayer dielectric ILD2 and may be connected to the conductive pad PAD. A plurality of bit lines BL may be arranged on the second interlayer dielectric ILD2. The bit lines BL may extend in parallel with each other. The bit lines BL may be electrically connected to the vertical channel structure VS through the bit line contact plugs BPLG and the conductive pad PAD.

Word line contact plugs WPLG may penetrate the second interlayer dielectric ILD2 and the first interlayer dielectric ILD1 and may be electrically connected to the electrodes EL forming a stepped structure. The word line contact plugs WPLG may further penetrate the insulation layer IL. A plurality of upper wirings UIL may be arranged on the second interlayer dielectric ILD2. The upper wirings UIL may be electrically connected to the electrodes EL respectively through the word line contact plugs WPLG.

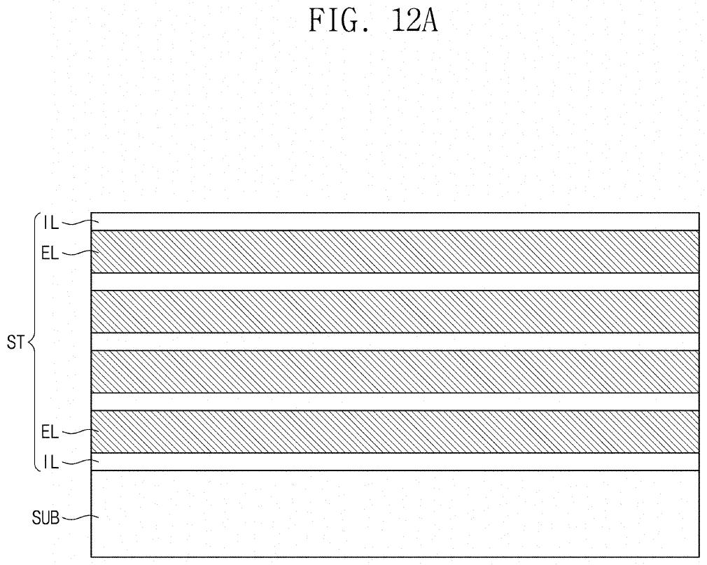

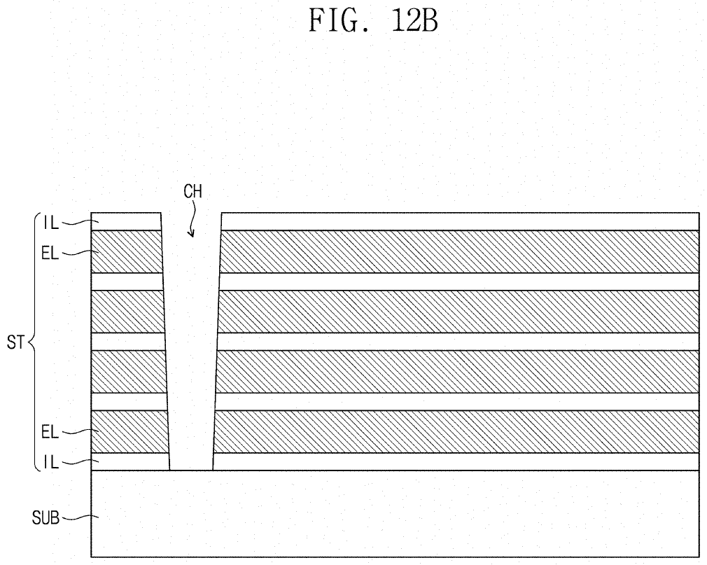

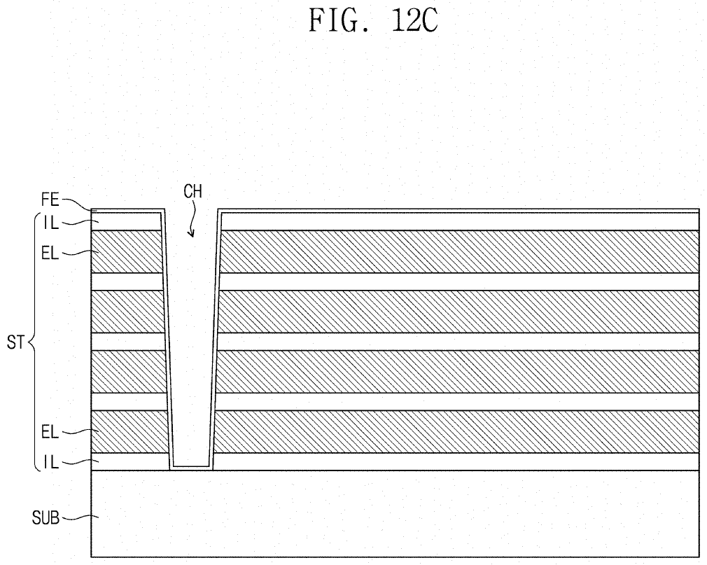

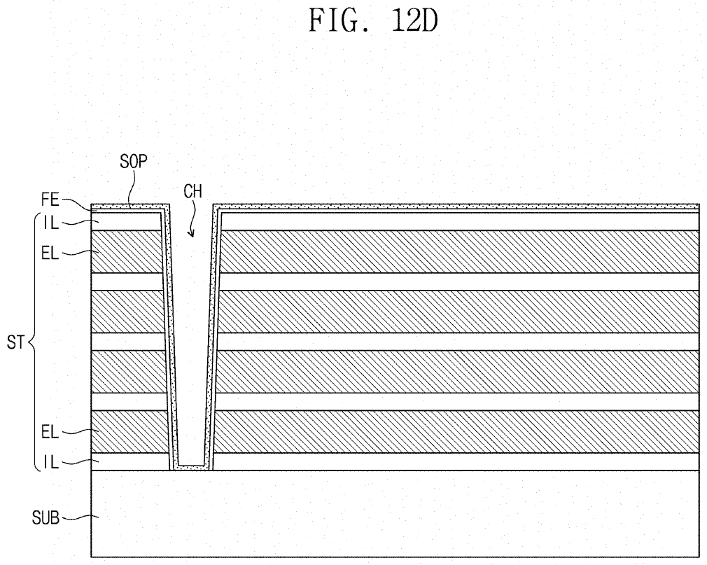

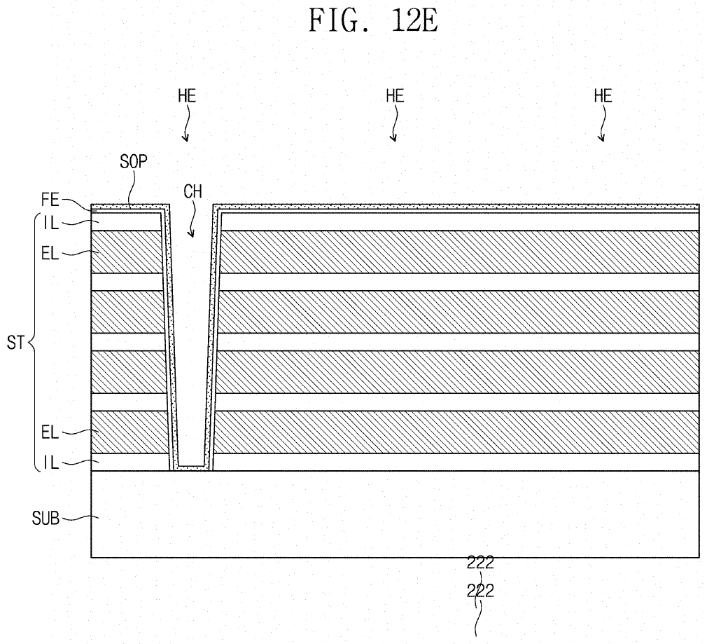

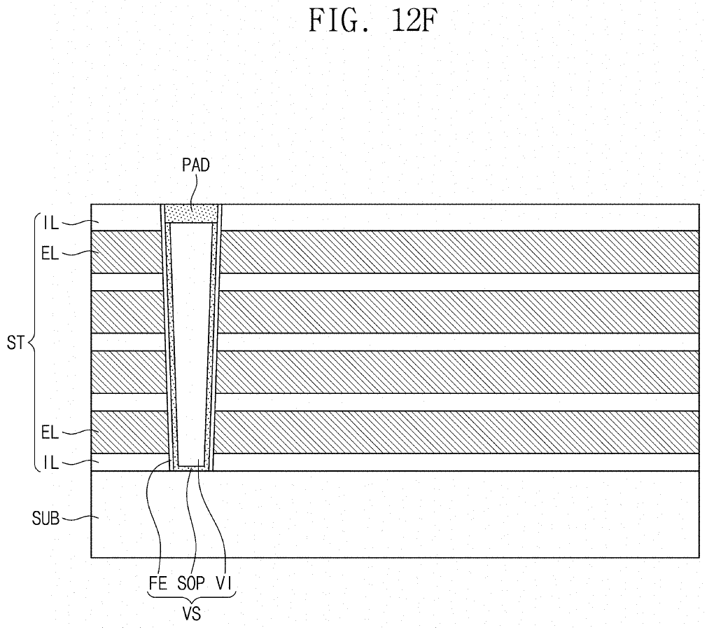

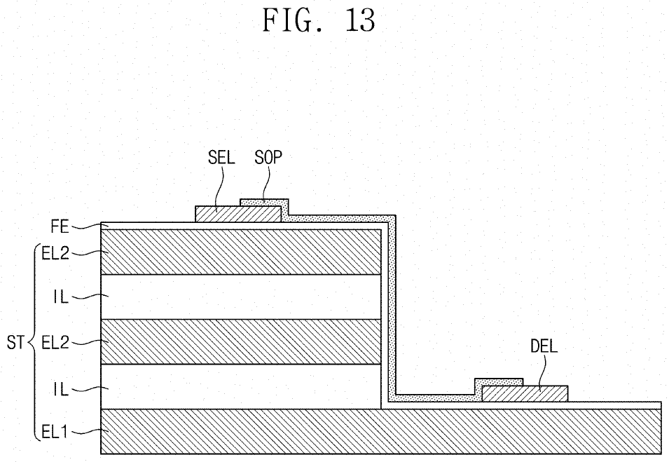

FIGS. 12A to 12F are cross-sectional views illustrating a method for manufacturing a semiconductor memory device according to embodiments of the inventive concept.

Referring to FIG. 12A, the electrode structure ST may be formed on the substrate SUB.

An upper portion of the substrate SUB may be doped with impurities. Therefore, the upper portion of the substrate SUB may have a conductive type and may function as a source of memory cells. The electrode structure ST may be formed by alternately stacking the insulation layers IL and the electrodes EL on the substrate SUB.

The insulation layers IL and the electrodes EL may be deposited using thermal chemical vapor deposition (THCVD), plasma enhanced chemical vapor deposition (PECVD), physical vapor deposition (PVD), or atomic layer deposition (ALD). The insulation layers IL may include a silicon oxide film, and the electrodes EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum).

Referring to FIG. 12B, a channel hole CH penetrating the electrode structure ST may be formed. The channel hole CH may expose an upper surface of the substrate SUB. Namely, since the upper surface of the substrate SUB is exposed by the channel hole CH, the oxide semiconductor layer SOP may be connected to an upper portion of the substrate SUB which may function as a source of memory cells.

In detail, forming the channel hole CH may include forming a mask pattern (not shown) having openings that define regions in which holes are to be formed on the electrode structure ST and anisotropically etching the electrode structure ST using the mask pattern as an etching mask. The anisotropic etching process may include plasma etching, reactive ion etching (RIE), inductively coupled plasma reactive ion etching (ICP-RIE), or ion beam etching (IBE) process.

Referring to FIG. 12C, the ferroelectric layer FE may be formed on an inner sidewall of the channel hole CH. For example, the ferroelectric layer FE may include a hafnium (Hf) oxide, and may further include at least one of zirconium (Zr), silicon (Si), aluminum (Al), gadolinium (Gd), or yttrium (Y). The ferroelectric layer FE may be conformally formed using an atomic layer deposition (ALD) process. The ferroelectric layer FE may extend towards an upper surface of the electrode structure ST.

Referring to FIG. 12D, a portion of the ferroelectric layer FE may be selectively removed. In detail, a portion of the ferroelectric layer FE contacting an upper surface of the substrate SUB may be removed. Therefore, the upper surface of the substrate SUB may be exposed.

The oxide semiconductor layer SOP may be formed on the ferroelectric layer FE. For example, the oxide semiconductor layer SOP may include at least one of In₂O₃, ZnO, IZO, IGO, ZTO, AZO, GZO, IGZO, IZTO, or HIZO. The oxide semiconductor layer SOP may be conformally formed using an atomic layer deposition (ALD) process. The oxide semiconductor layer SOP may extend along the ferroelectric layer FE. The oxide semiconductor layer SOP may vertically extend along the inner sidewall of the channel hole CH. The oxide semiconductor layer SOP may contact an upper surface of the substrate SUB. Namely, the oxide semiconductor layer SOP may contact an upper portion of the substrate SUB which functions as a source. A thermal expansion coefficient of the oxide semiconductor layer SOP may be different from a thermal expansion coefficient of the ferroelectric layer FE. The electron density of the oxide semiconductor layer SOP may be adjusted by temperature of the atomic layer deposition (ALD) process for depositing the oxide semiconductor layer SOP.

Referring to FIG. 12E, an annealing process HE may be performed on the oxide semiconductor layer SOP. The annealing process HE may be performed for about 1 second to about 600 seconds at a temperature of about 280° C. to about 1000° C. Preferably, the annealing process HE may be performed at a temperature of about 400° C. to about 600° C. The ferroelectric phase of the ferroelectric layer FE may be induced by the annealing process HE. In detail, the ferroelectric phase of the ferroelectric layer FE may be induced by performing the annealing process HE on the oxide semiconductor layer SOP. That is, the oxide semiconductor layer SOP may function as a capping layer for inducing the ferroelectric phase. Since the oxide semiconductor layer SOP is used as a capping layer, an additional interfacial layer may not be formed between the ferroelectric layer FE and the oxide semiconductor layer SOP. As a result, electrical characteristics of the semiconductor memory device may be improved.

Referring to FIG. 12F, the vertical channel structure VS may be formed in the channel hole CH. Forming the vertical channel structure VS may include forming the pillar VI in a residual portion of the channel hole CH and performing a planarization process on the pillar VI, the oxide semiconductor layer SOP, and the ferroelectric layer FE. The planarization process may be performed until an upper surface of an uppermost insulation layer IL is exposed. The oxide semiconductor layer SOP may be disposed between the pillar VI and the ferroelectric layer FE without being removed. Since the oxide semiconductor layer SOP is used as a channel of the semiconductor memory device, a process of removing the oxide semiconductor layer SOP is skipped, thus preventing occurrence of a surface defect in the ferroelectric layer FE.

The conductive pad PAD may be formed in the vertical channel structure VS. Forming the conductive pad PAD may include forming a recess by removing upper portions of the pillar VI and oxide semiconductor layer SOP and filling the recess with a semiconductor material and/or conductive material. The conductive pad PAD may cover an upper surface of the oxide semiconductor layer SOP and an upper surface of the pillar VI. A sidewall of the conductive pad PAD may contact the ferroelectric layer FE. The conductive pad PAD may include a semiconductor material and/or conductive material doped with impurities. A bit line contact plug BPLG may be electrically connected to the oxide semiconductor layer SOP through the conductive pad PAD. An upper surface of the conductive pad PAD and an upper surface of the ferroelectric layer FE may be substantially coplanar. The ferroelectric layer FE may be disposed between the conductive pad PAD and the electrode structure ST.

Referring back to FIG. 11, a stepped structure may be formed in the electrode structure ST. In detail, the stepped structure may be formed by performing a cycle process on the electrode structure ST. Forming the stepped structure may include forming a mask pattern (not shown) on the electrode structure ST and repeatedly performing a cycle multiple times using the mask pattern. One cycle may include a process of etching a portion of the electrode structure ST using the mask pattern as an etching mask and a trimming process of reducing the mask pattern.

The first interlayer dielectric ILD1 may be formed on the electrode structure ST. Forming the first interlayer dielectric ILD1 may include forming an insulation layer covering the electrode structure ST and performing a planarization process on the insulation layer until the uppermost insulation layer IL is exposed.

The second interlayer dielectric ILD2 may be formed on the electrode structure ST. The second interlayer dielectric IDL2 may cover the vertical channel structure VS.

The bit line contact plug BPLG may be formed, which penetrates the second interlayer dielectric ILD2 and are connected to the conductive pad PAD. The word line contact plugs WPLG may be formed, which penetrate the second interlayer dielectric ILD2 and are connected to the electrodes EL respectively. The bit line BL electrically connected to the bit line contact plug BPLG and the upper wirings UIL electrically connected to the word line contact plugs WPLG may be formed on the second interlayer dielectric ILD2.

FIG. 13 is a cross-sectional view of a semiconductor memory device according to embodiments of the inventive concept.

Referring to FIG. 13, the ferroelectric layer FE may be provided on the electrode structure ST. The electrode structure ST may include a first electrode EL1, second electrodes EL2, and insulation layers IL. The first electrode EL1 may be provided in a lowermost portion of the electrode structure ST. The second electrodes EL2 and the insulation layers IL may be alternately stacked on the first electrode EL1 in a vertical direction. The insulation layers IL may separate the stacked first electrode EL1 and second electrodes EL2 from each other. The numbers of the second electrodes EL2 and insulation layers IL are not limited to the numbers illustrated in the drawings.

The electrode structure ST may have a stepped structure. For example, a width of the first electrode EL1 may be larger than widths of the second electrodes EL2 and insulation layers IL. The second electrodes EL2 and the insulation layers IL may have substantially the same width. For example, the first and second electrodes EL1 and EL2 and the insulation layers IL may have substantially the same thickness.

Each of the first electrode EL1 and the second electrodes EL2 may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum). The insulation layers IL may include a silicon oxide film. The first and second electrodes EL1 and EL2 of the electrode structure ST may be used as gate electrodes of transistors.

The ferroelectric layer FE may be conformally provided on the electrode structure ST. For example, the ferroelectric layer FE may include a hafnium (Hf) oxide, and may further include at least one of zirconium (Zr), silicon (Si), aluminum (Al), gadolinium (Gd), or yttrium (Y). A ferroelectric phase of the ferroelectric layer FE may be induced by the oxide semiconductor layer SOP described below.

The ferroelectric layer FE may extend along an upper surface of an uppermost second electrode EL2, sidewalls of the insulation layers IL and second electrodes EL2, and an upper surface of the first electrode EL1.

The source electrode SEL and the drain electrode DEL may be provided on the ferroelectric layer FE. For example, the source electrode SEL may be provided on the uppermost second electrode EL2, and the drain electrode DEL may be provided below the second electrodes EL2. The source electrode SEL may vertically overlap the second electrodes EL2. The drain electrode DEL may vertically overlap a portion of the first electrode EL1 exposed by the insulation layers IL. The source electrode SEL and the drain electrode DEL may be positioned at different levels. For example, the source electrode SEL and the drain electrode DEL may include a metal material such as aluminum (Al), tungsten (W), molybdenum (Mo), etc.

The oxide semiconductor layer SOP may be conformally provided on the ferroelectric layer FE, the source electrode SEL, and the drain electrode DEL. The oxide semiconductor layer SOP may extend along an upper surface of an uppermost second electrode EL2, sidewalls of the insulation layers IL and second electrodes EL2, and an upper surface of the first electrode EL1.

The oxide semiconductor layer SOP may contact the source electrode SEL and the drain electrode DEL. For example, the oxide semiconductor layer SOP may further extend along an upper surface and sidewall of the source electrode SEL. The oxide semiconductor layer SOP may further extend along an upper surface and sidewall of the drain electrode DEL.

The oxide semiconductor layer SOP may include an oxide semiconductor material. For example, the oxide semiconductor layer SOP may include at least one of In₂O₃, ZnO, IZO, IGO, ZTO, AZO, GZO, IGZO, IZTO, or HIZO. The oxide semiconductor layer SOP may be used as a channel of transistors. A thermal expansion coefficient of the oxide semiconductor layer SOP may be different from a thermal expansion coefficient of the ferroelectric layer FE. The oxide semiconductor layer SOP and the ferroelectric layer FE may not have an additional interfacial layer therebetween, and thus may physically contact each other.

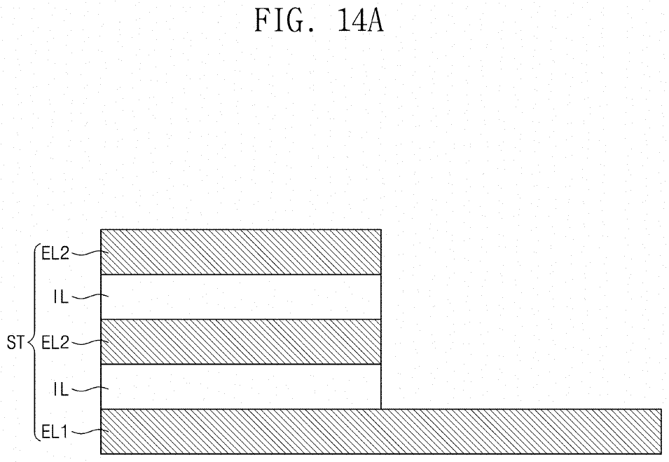

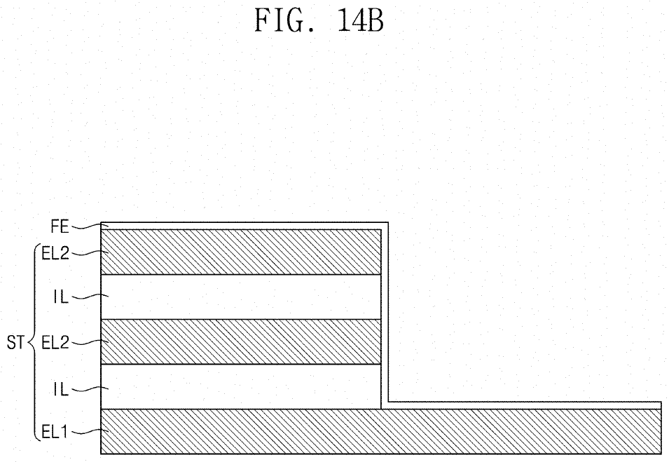

FIGS. 14A and 14B are cross-sectional views illustrating a method for manufacturing a semiconductor memory device according to embodiments of the inventive concept.

Referring to FIG. 14A, electrode films (not shown) and the insulation layers IL may be alternately stacked so as to form a laminate structure (not shown). An etching process may be performed on the laminate structure (not shown). The etching process may include plasma etching, reactive ion etching (RIE), inductively coupled plasma reactive ion etching (ICP-RIE), or ion beam etching (IBE) process. The electrode films (not shown) and the insulation layers IL may be partially and selectively etched by the etching process. A lowermost electrode film among the electrode films (not shown) may not be etched. A portion of an upper surface of the lowermost electrode film may be exposed. The lowermost electrode film may constitute the first electrode EL1. The electrode structure ST including the first electrode ELL the second electrodes EL2, and the insulation layers IL may be formed by the etching process.

The second electrodes EL2 and the insulation layers IL may be alternately formed on the first electrode EL1 in a vertical direction. The insulation layers IL may separate the stacked first electrode EL1 and second electrodes EL2 from each other. The electrode structure ST may have a stepped structure. For example, a width of the first electrode EL1 may be larger than widths of the second electrodes EL2 and insulation layers IL. The second electrodes EL2 and the insulation layers IL may have substantially the same width.

Referring to FIG. 14B, the ferroelectric layer FE may be formed on the electrode structure ST. The ferroelectric layer FE may be conformally formed on the electrode structure ST using an atomic layer deposition (ALD) process. The ferroelectric layer FE may extend along an upper surface of an uppermost second electrode EL2, sidewalls of the insulation layers IL and second electrodes EL2, and an upper surface of the first electrode EL1.

Referring back to FIG. 13, the source electrode SEL and the drain electrode DEL may be formed on the ferroelectric layer FE. For example, the source electrode SEL may be formed on the uppermost second electrode EL2, and the drain electrode DEL may be formed below the second electrodes EL2. Namely, the source electrode SEL may vertically overlap the second electrodes EL2, and the drain electrode DEL may vertically overlap a portion of the first electrode EL1 exposed by the insulation layers IL. The source electrode SEL and the drain electrode DEL may be positioned at different levels.

Thereafter, the oxide semiconductor layer SOP may be formed. The oxide semiconductor layer SOP may be conformally formed on the ferroelectric layer FE, the source electrode SEL, and the drain electrode DEL using an atomic layer deposition (ALD) process. The oxide semiconductor layer SOP may extend along an upper surface of an uppermost second electrode EL2, sidewalls of the insulation layers IL and second electrodes EL2, and an upper surface of the first electrode EL1. The oxide semiconductor layer SOP may contact the source electrode SEL and the drain electrode DEL. For example, the oxide semiconductor layer SOP may further extend along an upper surface and sidewall of the source electrode SEL. The oxide semiconductor layer SOP may further extend along an upper surface and sidewall of the drain electrode DEL.

An annealing process may be performed on the oxide semiconductor layer SOP. The annealing process may be performed for about 1 second to about 600 seconds at a temperature of about 280° C. to about 1000° C. Preferably, the annealing process may be performed at a temperature of about 400° C. to about 600° C. The ferroelectric phase of the ferroelectric layer FE may be induced by the annealing process performed on the oxide semiconductor layer SOP. That is, the oxide semiconductor layer SOP may function as a capping layer for inducing the ferroelectric phase of the ferroelectric layer FE.

The oxide semiconductor layer SOP may have an electron density of about 10¹⁵ cm⁻³ to about 10²¹ cm⁻³. The electron density of the oxide semiconductor layer SOP may be adjusted according to a polarization magnitude of the ferroelectric layer FE and a thickness of the oxide semiconductor layer SOP. Furthermore, the electron density may be adjusted by temperature of the atomic layer deposition (ALD) process for depositing the oxide semiconductor layer SOP.

The oxide semiconductor layer SOP may remain without being removed after inducing the ferroelectric phase of the ferroelectric layer FE. That is, the oxide semiconductor layer SOP may function as a capping layer and channel of the semiconductor memory device.

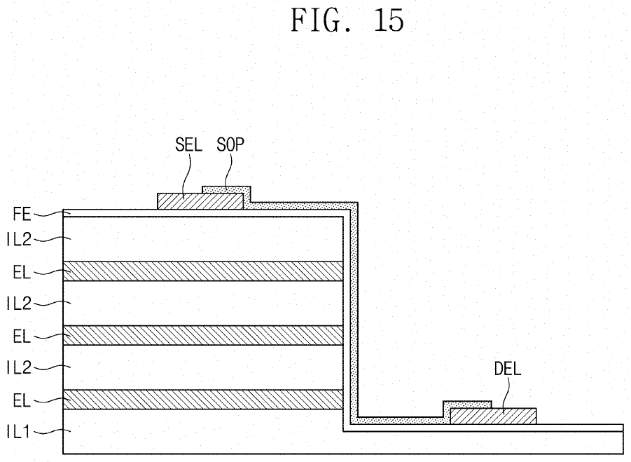

FIG. 15 is a cross-sectional view of a semiconductor memory device according to embodiments of the inventive concept.

Referring to FIG. 15, the ferroelectric layer FE may be provided on the electrode structure ST. The electrode structure ST may include a first insulation layer IL1, second insulation layers IL2, and electrodes EL. The first insulation layer IL1 may be provided in a lowermost portion of the electrode structure ST. The second insulation layers IL2 and the electrodes EL may be alternately stacked on the first insulation layer IL1 in a vertical direction. The second insulation layers IL2 may separate the stacked electrodes EL from each other. The numbers of the electrodes EL and second insulation layers IL2 are not limited to the numbers illustrated in the drawings. For example, the first insulation layer IL1 may have a stepped structure.

The electrode structure ST may have a stepped structure. For example, a width of the first insulation layer IL1 may be larger than widths of the second insulation layers IL2 and electrodes EL. The second insulation layers IL2 and the electrodes EL may have substantially the same width. A thickness of each of the electrodes EL may be less than a thickness of each of the first and second insulation layers IL1 and IL2.

The electrodes EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum). Each of the first and second insulation layers IL1 and IL2 may include a silicon oxide film. The electrodes EL of the electrode structure ST may be used as gate electrodes of transistors.

The ferroelectric layer FE may be conformally provided on the electrode structure ST. For example, the ferroelectric layer FE may include a hafnium (Hf) oxide, and may further include at least one of zirconium (Zr), silicon (Si), aluminum (Al), gadolinium (Gd), or yttrium (Y). A ferroelectric phase of the ferroelectric layer FE may be induced by the oxide semiconductor layer SOP described below.

The ferroelectric layer FE may extend along an upper surface of an uppermost second insulation layer IL2, sidewalls of the electrodes EL and second insulation layers IL2, and an upper surface of the first insulation layer IL1. For example, a level of a lowermost surface of the ferroelectric layer FE may be lower than a level of an uppermost surface of the first insulation layer IL1. For another example, although not illustrated, the level of the lowermost surface of the ferroelectric layer FE may be substantially the same as the level of the uppermost surface of the first insulation layer IL1.

The source electrode SEL and the drain electrode DEL may be provided on the ferroelectric layer FE. For example, the source electrode SEL may be provided on the uppermost second insulation layer IL2, and the drain electrode DEL may be provided below the second insulation layers IL2. The source electrode SEL may vertically overlap the second insulation layer IL2. The drain electrode DEL may vertically overlap a portion of the first insulation layer IL1 exposed by the electrodes EL. The source electrode SEL and the drain electrode DEL may be positioned at different levels. For example, the source electrode SEL and the drain electrode DEL may include a metal material such as aluminum (Al), tungsten (W), molybdenum (Mo), etc.

The oxide semiconductor layer SOP may be conformally provided on the ferroelectric layer FE, the source electrode SEL, and the drain electrode DEL. The oxide semiconductor layer SOP may extend along an upper surface of an uppermost second insulation layer IL2, sidewalls of the electrodes EL and second insulation layers IL2, and an upper surface of the first insulation layer IL1.

The oxide semiconductor layer SOP may contact the source electrode SEL and the drain electrode DEL. For example, the oxide semiconductor layer SOP may further extend along an upper surface and sidewall of the source electrode SEL. The oxide semiconductor layer SOP may further extend along an upper surface and sidewall of the drain electrode DEL.

The oxide semiconductor layer SOP may include an oxide semiconductor material. For example, the oxide semiconductor layer SOP may include at least one of In₂O₃, ZnO, IZO, IGO, ZTO, AZO, GZO, IGZO, IZTO, or HIZO. The oxide semiconductor layer SOP may be used as a channel of transistors. A thermal expansion coefficient of the oxide semiconductor layer SOP may be different from a thermal expansion coefficient of the ferroelectric layer FE. The oxide semiconductor layer SOP and the ferroelectric layer FE may not have an additional interfacial layer therebetween, and thus may physically contact each other.

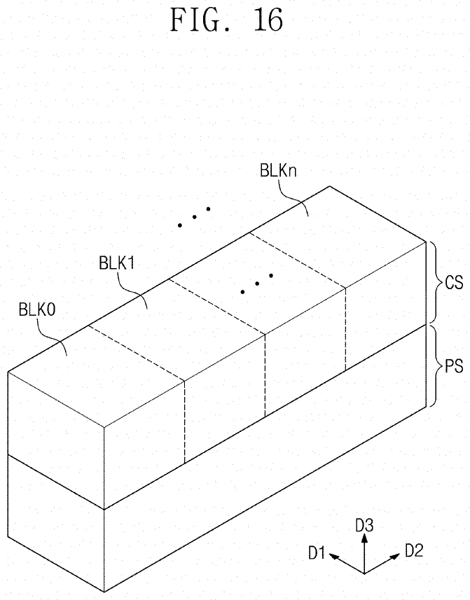

FIG. 16 is a schematic perspective view of a semiconductor memory device according to embodiments of the inventive concept.

Referring to FIG. 16, the semiconductor memory device according to embodiments of the inventive concept may include a peripheral circuit structure PS, a cell array structure CS on the peripheral circuit structure PS, and a through-contact (not shown) vertically connecting the cell array structure CS and the peripheral circuit structure PS. In a plan view, the cell array structure CS may overlap the peripheral circuit structure PS.

In embodiments of the inventive concept, the peripheral circuit structure PS may include row and column decoders, a page buffer, control circuits, and peripheral logic circuits. The peripheral logic circuits constituting the peripheral circuit structure PS may be integrated on a semiconductor substrate.

The cell array structure CS may include a cell array including a plurality of three-dimensionally arranged memory cells. In detail, the cell array structure CS may include a plurality of memory blocks BLK0 to BLKn. Each of the memory blocks BLK0 to BLKn may include three-dimensionally arranged memory cells.

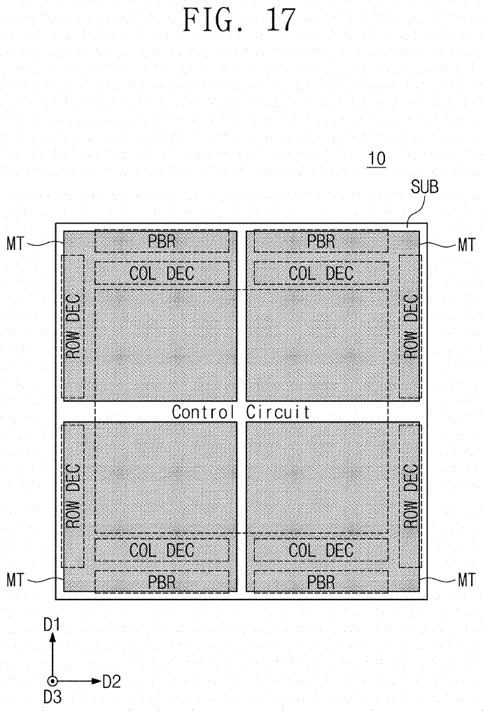

FIG. 17 is a schematic plan view of a semiconductor memory device according to embodiments of the inventive concept.

Referring to FIGS. 16 and 17, the peripheral circuit structure PS and the cell array structure CS, described above with reference to FIG. 16, may be arranged on a first substrate SUB. In each of chip regions 10, low and column decoders ROW DEC and COL DEC, a page buffer PBR, and control circuits, which constitute the peripheral structure PS, may be arranged on the first substrate SUB.

A plurality of mats MT constituting the cell array structure CS may be arranged on the first substrate SUB. The mats MT may be arranged in a first direction D1 and second direction D2. Each of the mats MT may include the memory blocks BLK0 to BLKn described above with reference to FIG. 16.

The mats MT may be arranged overlapping the peripheral circuit structure PS. According to embodiments of the inventive concept, the peripheral logic circuits constituting the peripheral circuit structure PS may be freely arranged under the mats MT.

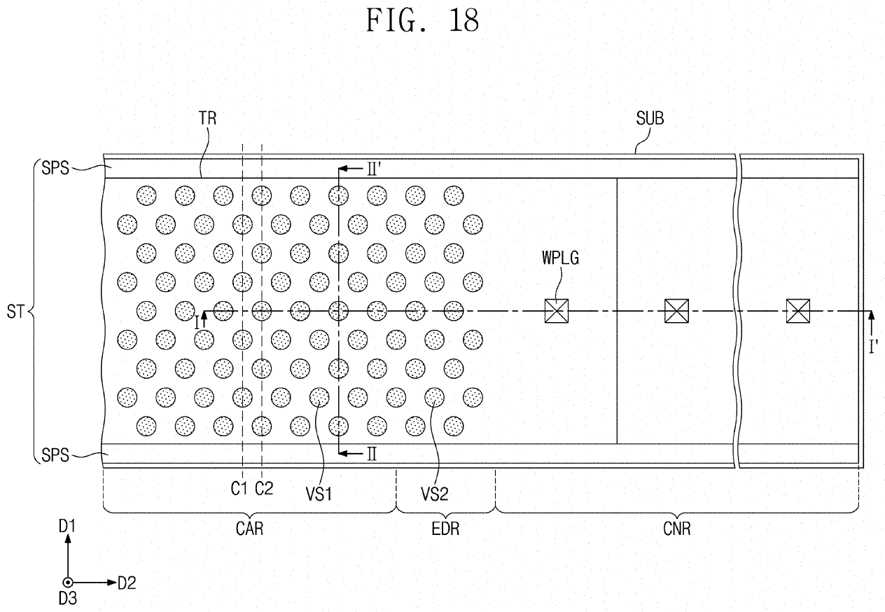

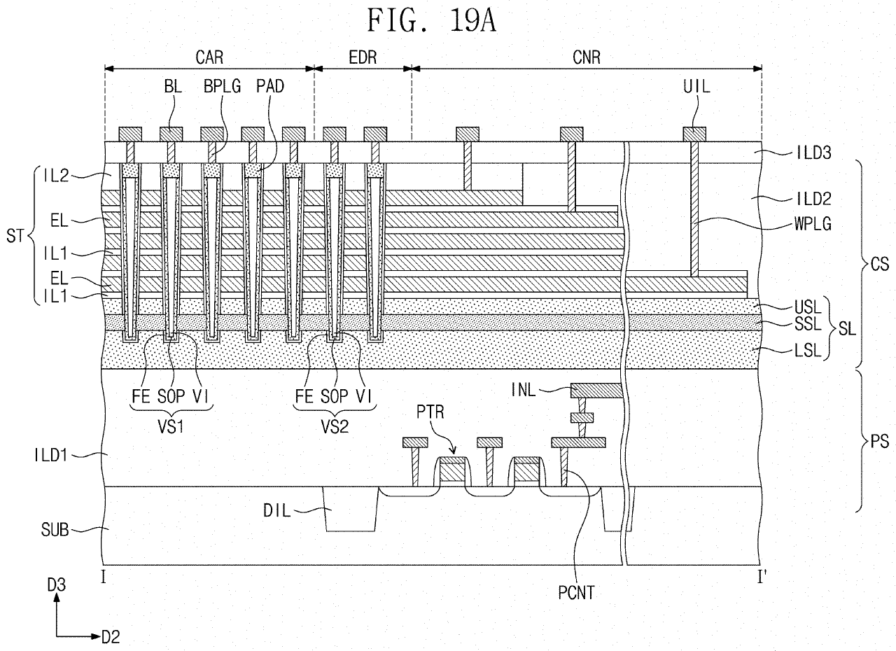

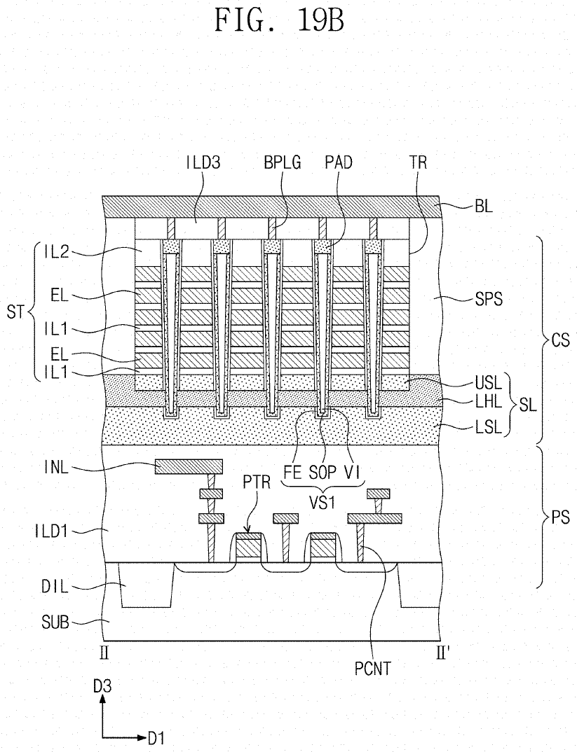

FIG. 18 is a plan view for describing a semiconductor memory device according to embodiments of the inventive concept. FIGS. 19A and 19B are cross-sectional views of the semiconductor memory device taken along line I-I′ and line II-II′ of FIG. 18, respectively. The semiconductor memory device illustrated in FIG. 18 is an example of a memory cell structure of any one of the mats MT of FIG. 17.

Referring to FIGS. 18, 19A, and 19B, the peripheral circuit structure PS including peripheral transistors PTR may be arranged on the first substrate SUB. The cell array structure CS including the electrode structure ST may be arranged on the peripheral circuit structure PS. The first substrate SUB may be a monocrystalline epitaxial layer grown on a silicon substrate, silicon-germanium substrate, germanium substrate, or monocrystalline silicon substrate. The first substrate SUB may include active regions defined by a device isolation layer DIL.

The peripheral circuit structure PS may include a plurality of peripheral transistors PTR arranged in the active regions on the first substrate SUB. As described above, the peripheral transistors PTR may constitute row and column decoders, a page buffer, control circuit, and peripheral logic circuit.

The peripheral circuit structure PS may further include lower wirings INL provided on the peripheral transistors PTR and the first interlayer dielectric ILD1 covering the peripheral transistors PTR and the lower wirings INL. A peripheral contact PCNT that electrically connects the lower wiring INL and the peripheral transistor PTR may be provided therebetween. The first interlayer dielectric ILD1 may include insulation films stacked in multiple layers. For example, the first interlayer dielectric ILD1 may include a silicon oxide film, silicon nitride film, silicon oxynitride film, and/or low-k dielectric film.

The cell array structure CS may be provided on the first interlayer dielectric ILD1 of the peripheral circuit structure PS. Hereinafter, the cell array structure CS will be described in more detail. A second substrate SL may be provided on the first interlayer dielectric ILD1. For example, the second substrate SL may have a quadrilateral plate shape constituting a lower portion of the mat MT. The second substrate SL may support the electrode structure ST provided thereon.

The second substrate SL may include a lower semiconductor layer LSL, a source semiconductor layer SSL, and an upper semiconductor layer USL, which are sequentially stacked. The lower semiconductor layer LSL, the source semiconductor layer SSL, and the upper semiconductor layer USL may include a semiconductor material (e.g., at least one of silicon (Si), germanium (Ge), silicon germanium (SiGe), gallium arsenide (GaAs), indium gallium arsenide (InGaAs), aluminum gallium arsenide (AlGaAs), or mixtures thereof). Each of the lower semiconductor layer LSL, the source semiconductor layer SSL, and the upper semiconductor layer USL may be single crystal, amorphous, and/or polycrystalline. For example, each of the lower semiconductor layer LSL, the source semiconductor layer SSL, and the upper semiconductor layer USL may include a polysilicon film doped with impurities and having an N type. The lower semiconductor layer LSL, the source semiconductor layer SSL, and the upper semiconductor layer USL may have different concentrations of impurities.

The source semiconductor layer SSL may be disposed between the lower semiconductor layer LSL and the upper semiconductor layer USL. Due to the source semiconductor layer SSL, the lower semiconductor layer LSL and the upper semiconductor layer USL may be electrically connected to each other. For example, in a plan view, the upper semiconductor layer USL and the source semiconductor layer SSL may overlap the lower semiconductor layer LSL.

The second substrate SL may include a cell array region CAR, a cell edge region EDR, and a connection region CNR. The cell array region CAR may be provided in a center of the second substrate SL. The connection region CNR may be provided on one side of the second substrate SL. The connection region CNR may extend from one side of the cell array region CAR in the second direction D2. The cell edge region EDR may be provided at an outer periphery of the cell array region CAR. The cell edge region EDR may be disposed between the cell array region CAR and the connection region CNR.

The electrode structure ST may be provided on the second substrate SL. The second interlayer dielectric ILD2 may be provided on the second substrate SL. An upper surface of the second interlayer dielectric ILD2 and an upper surface of the electrode structure ST may be coplanar. The second interlayer dielectric ILD2 may cover the electrode structure ST in the connection region CNR.

The electrode structure ST may include the electrodes EL stacked in a direction (i.e., third direction D3) perpendicular to the second substrate SL. The electrode structure ST may further include the first insulation layers IL1 separating the stacked electrodes EL from each other. The first insulation layers IL1 and the electrodes EL of the electrode structure ST may be alternately stacked in the third direction D3. The second insulation layer IL2 may be provided in an uppermost portion of the electrode structure ST. The second insulation layer IL2 may be thicker than each of the first insulation layer IL1.

The electrode structure ST may extend from the cell array region CAR to the connection region CNR. The electrode structure ST may have a stepped structure in the connection region CNR. The stepped structure of the electrode structure ST may have a height that decreases in a direction away from the cell array region CAR. Namely, the height of the stepped structure of the electrode structure ST may decrease in the second direction D2 from the cell array region CAR.

A lowermost electrode EL among the electrodes EL of the electrode structure ST may be a lower selection line. An uppermost electrode EL among the electrodes EL of the electrode structure ST may be an upper selection line. The electrodes EL except for the lower selection line and the upper selection line may be word lines.

The electrodes EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum). The first and second insulation layers IL1 and IL2 may include a silicon oxide film.

A plurality of first vertical channel structures VS1 penetrating the electrode structure ST may be provided in the cell array region CAR. For example, referring to FIG. 18, four of the first vertical channel structures VS1 may be arranged in the first direction D1 so as to form a first column C1, and five of the first vertical channel structures VS1 may be arranged in the first direction D1 so as to form a second column C2. The first columns C1 and the second columns C2 may be alternately arranged in the second direction D2. A diameter of each of the first vertical channel structures VS1 may gradually reduce towards the first substrate SUB.

A plurality of second vertical channel structures VS2 penetrating the electrode structure ST may be provided in the cell edge region EDR. The second vertical channel structures VS2 may have the same arrangement and pattern density as the first vertical channel structures VS1 described above, except that the second vertical channel structures VS2 are arranged in the cell edge region EDR.

Each of the first and second vertical channel structures VS1 and VS2 may include the ferroelectric layer FE, the oxide semiconductor layer SOP, and the pillar VI. The oxide semiconductor layer SOP may be disposed between the ferroelectric layer FE and the pillar VI. The conductive pad PAD may be provided in each of the first and second vertical channel structures VS1 and VS2.

The pillar VI may have a cylindrical shape. The oxide semiconductor layer SOP may extend in a vertical direction (i.e., third direction D3) from the lower semiconductor layer LSL to the conductive pad PAD, covering a surface of the pillar VI. The oxide semiconductor layer SOP may have a pipe shape, an upper end of which is open. The ferroelectric layer FE may extend in the third direction D3 from the lower semiconductor layer LSL to the second insulation layer IL2, covering an outer surface of the oxide semiconductor layer. The ferroelectric layer FE may also have a pipe shape, an upper end of which is open. The ferroelectric layer FE may be disposed between the electrode structure ST and the oxide semiconductor layer SOP.

For example, the ferroelectric layer FE may include a hafnium (Hf) oxide, and may further include at least one of zirconium (Zr), silicon (Si), aluminum (Al), gadolinium (Gd), or yttrium (Y). The ferroelectric phase of the ferroelectric layer FE may be induced by the oxide semiconductor layer SOP.

The oxide semiconductor layer SOP may include an oxide semiconductor material. For example, the oxide semiconductor layer SOP may include at least one of In₂O₃, ZnO, IZO, IGO, ZTO, AZO, GZO, IGZO, IZTO, or HIZO. The oxide semiconductor layer SOP may be used as a channel of transistors constituting a NAND cell string. A thermal expansion coefficient of the oxide semiconductor layer SOP may be different from a thermal expansion coefficient of the ferroelectric layer FE. The oxide semiconductor layer SOP and the ferroelectric layer FE may not have an additional interfacial layer therebetween, and thus may physically contact each other. The oxide semiconductor layer SOP may have an electron density of about 10¹⁵ cm⁻³ to about 10²¹ cm⁻³. The electron density of the oxide semiconductor layer SOP may be adjusted according to a polarization magnitude of the ferroelectric layer FE and a thickness of the oxide semiconductor layer SOP. The pillar VI may include, for example, a silicon oxide film.

The conductive pad PAD may cover an upper surface of the oxide semiconductor layer SOP and an upper surface of the pillar VI. A sidewall of the conductive pad PAD may contact the ferroelectric layer FE. The conductive pad PAD may include a semiconductor material and/or conductive material doped with impurities. A bit line contact plug BPLG may be electrically connected to the oxide semiconductor layer SOP through the conductive pad PAD.

The source semiconductor layer SSL may directly contact a lower sidewall of each of the oxide semiconductor layers SOP. The source semiconductor layer SSL may electrically connect the plurality of oxide semiconductor layers SOP to each other. Namely, the oxide semiconductor layers SOP may be electrically connected together to the second substrate SL. The second substrate SL may function as a source of memory cells. A common source voltage may be applied to the second substrate SL.

A plurality of separation structures SPS may penetrate the electrode structure ST. The separation structures SPS may extend parallel in the second direction D2. The electrode structure ST may be horizontally divided into a plurality of structures by the separation structures SPS. For example, one electrode EL of the electrode structure ST may be horizontally divided into a plurality of electrodes by the separation structures SPS. The separation structures SPS may include an insulation material such as a silicon oxide.

The semiconductor memory device according to embodiments of the inventive concept may be a three-dimensional NAND flash memory device. NAND cell strings may be integrated in the electrode structure ST on the second substrate SL. That is, the electrode structure ST and the first and second vertical channel structures VS1 and VS2 penetrating therethrough may constitute memory cells three-dimensionally arranged on the second substrate SL. The electrodes EL of the electrode structure ST may be used as gate electrodes of transistors.

A third interlayer dielectric ILD3 may be provided on the second interlayer dielectric ILD2. The bit line contact plugs BPLG may penetrate the third interlayer dielectric ILD3 and may be respectively connected to the conductive pads PAD. A plurality of bit lines BL may be arranged on the third interlayer dielectric ILD3. The bit lines BL may extend parallel in the first direction D1. The bit lines BL may be electrically connected to the first and second vertical channel structures VS1 and VS2 through the bit line contact plugs BPLG, respectively.

Word line contact plugs WPLG may penetrate the third interlayer dielectric ILD3 and may be respectively connected to the electrodes EL. The word line contact plugs WPLG may further penetrate the second interlayer dielectric ILD2 or the second insulation layer IL2. A plurality of upper wirings UIL may be arranged on the third interlayer dielectric ILD3. The upper wirings UIL may extend parallel in the first direction D1. The upper wirings UIL may be electrically connected to the electrodes EL respectively through the word line contact plugs WPLG. The word line contact plugs WPLG and the upper wirings UIL may be arranged in the connection region CNR.

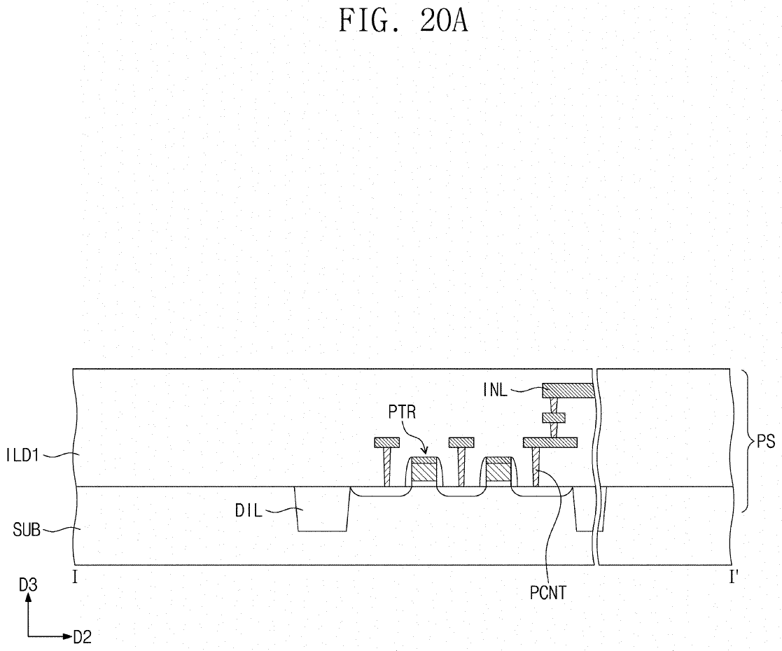

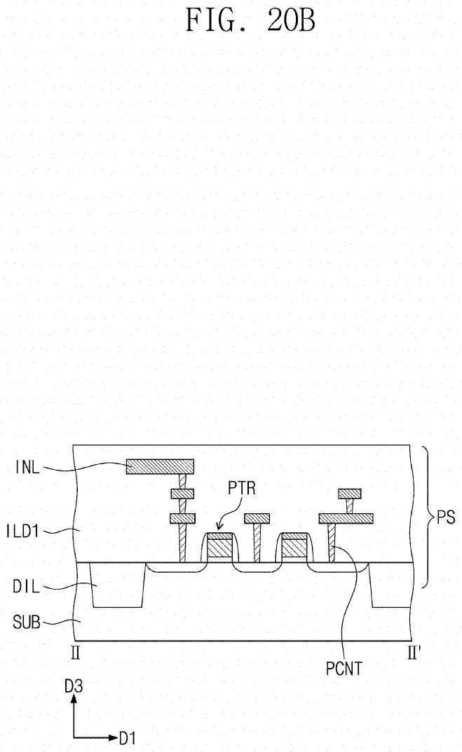

FIGS. 20A, 21A, 22A, 23A, 24A, 25A, and 26A, which are for describing a method for manufacturing a semiconductor memory device according to embodiments of the inventive concept, are cross-sectional views of the semiconductor memory device taken along line I-I′ of FIG. 18. FIGS. 20B, 21B, 22B, 23B, 24B, 25B, and 26B, which are for describing the method for manufacturing the semiconductor memory device according to embodiments of the inventive concept, are cross-sectional views of the semiconductor memory device taken along line II-II′ of FIG. 18.

Referring to FIGS. 18, 20A, and 20B, the peripheral circuit structure PS may be formed on the first substrate SUB. Forming the peripheral circuit structure PS may include forming the peripheral transistors PTR on the first substrate SUB and forming the lower wirings INL on the peripheral transistors PTR. For example, forming the peripheral transistors PTR may include forming a device isolation layer DIL defining active regions on the first substrate SUB, forming a gate dielectric and a gate electrode in the active regions, and forming source/drain regions by injecting impurities into the active regions. The first interlayer dielectric ILD1 covering the peripheral transistors PTR and the lower wirings INL may be formed.

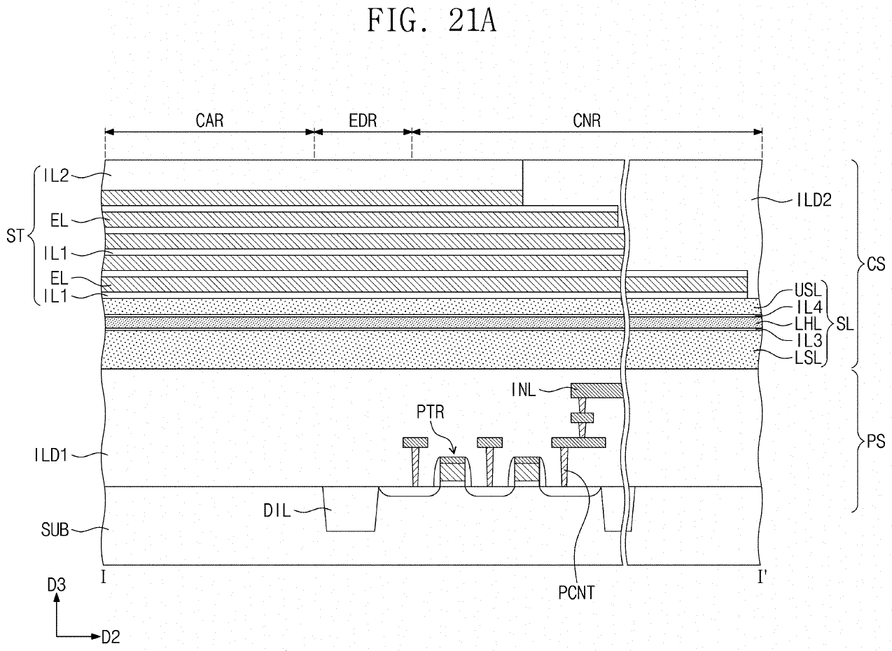

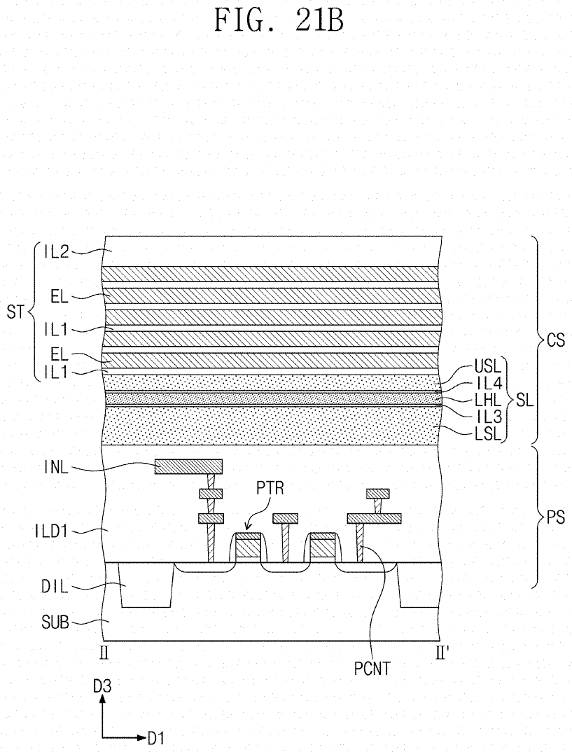

Referring to FIGS. 18, 21A, and 21B, the second substrate SL may be formed on the first interlayer dielectric ILD1. Forming the second substrate SL may include sequentially forming a lower semiconductor layer LSL, a third insulation layer IL3, a lower sacrificial layer LHL, a fourth insulation layer IL4, and an upper semiconductor layer USL. For example, the lower semiconductor layer LSL and the upper semiconductor layer USL may include a semiconductor material such as polysilicon. The third and fourth insulation layers IL3 and IL4 may include a silicon oxide film, and the lower sacrificial layer LHL may include a silicon nitride film or silicon oxynitride film.

The electrode structure ST may be formed on the second substrate SL. In detail, the electrode structure ST may be formed by alternately stacking the first insulation layers IL1 and the electrodes EL on the upper semiconductor layer USL. The second insulation layer IL2 may be formed in an uppermost portion of the electrode structure ST. The first insulation layers IL1, the electrodes EL, and the second insulation layer IL2 may be deposited using thermal chemical vapor deposition (THCVD), plasma enhanced chemical vapor deposition (PECVD), physical vapor deposition (PVD), or atomic layer deposition (ALD). The first insulation layers IL1 and the second insulation layers IL2 may include a silicon oxide film. The electrodes EL may include a conductive material selected from the group consisting of a doped semiconductor (e.g., doped silicon), metal (e.g., tungsten, copper, or aluminum), conductive metal nitride (e.g., titanium nitride or tantalum nitride), and transition metal (e.g., titanium or tantalum).

A stepped structure may be formed in the electrode structure ST in the connection region CNR. In detail, the stepped structure may be formed in the connection region CNR by performing a cycle process on the electrode structure ST. Forming the stepped structure may include forming a mask pattern (not shown) on the electrode structure ST and repeatedly performing a cycle multiple times using the mask pattern. One cycle may include a process of etching a portion of the electrode structure ST using the mask pattern as an etching mask and a trimming process of reducing the mask pattern.

The second interlayer dielectric ILD2 may be formed on the electrode structure ST. Forming the second interlayer dielectric ILD2 may include forming an insulation film covering the electrode structure ST and performing a planarization process on the insulation film until the second insulation layer IL2 is exposed.

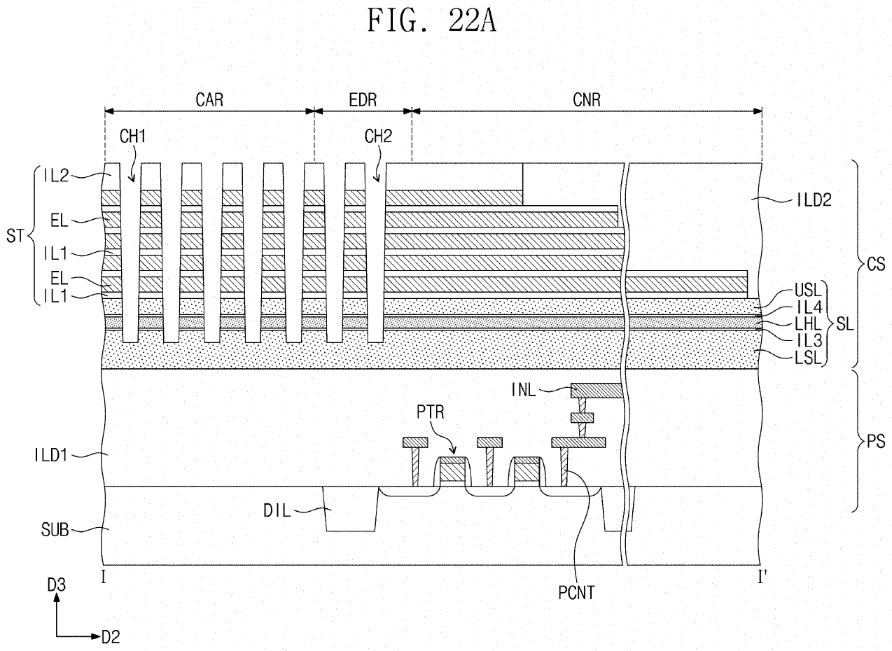

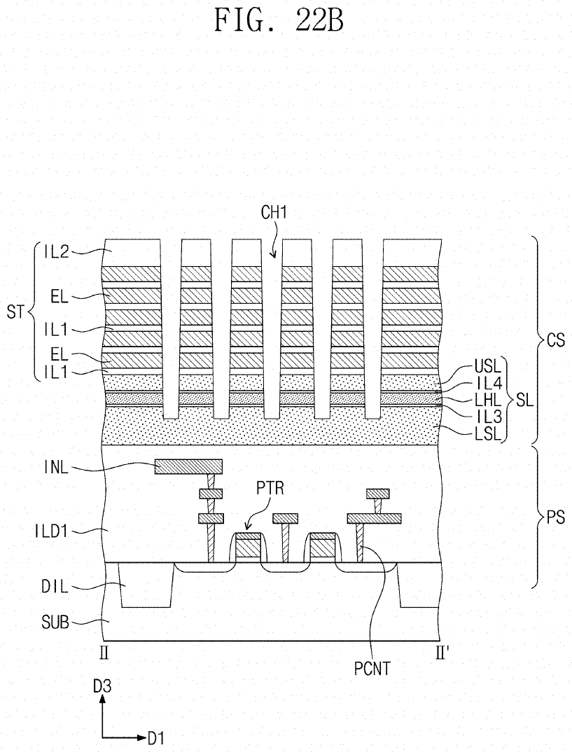

Referring to FIGS. 18, 22A, and 22B, first channel holes CH1 penetrating the electrode structure ST may be formed in the cell array region CAR. Second channel holes CH2 penetrating the electrode structure ST may be formed in the cell edge region EDR. The first and second channel holes CH1 and CH2 may expose the lower semiconductor layer LSL.

In detail, forming the first and second channel holes CH1 and CH2 may include forming a mask pattern (not shown) having openings that define regions in which holes are to be formed on the electrode structure ST and anisotropically etching the electrode structure ST using the mask pattern as an etching mask. The anisotropic etching process may include plasma etching, reactive ion etching (RIE), inductively coupled plasma reactive ion etching (ICP-RIE), or ion beam etching process.

In a plan view, the first and second channel holes CH1 and CH2 may be arranged along one direction or may be arranged zigzaggedly. The descriptions of the planar arrangement of the first and second vertical channel structures VS1 and VS2 provided above with reference to FIG. 15 may be applied to the first and second channel holes CH1 and CH2.

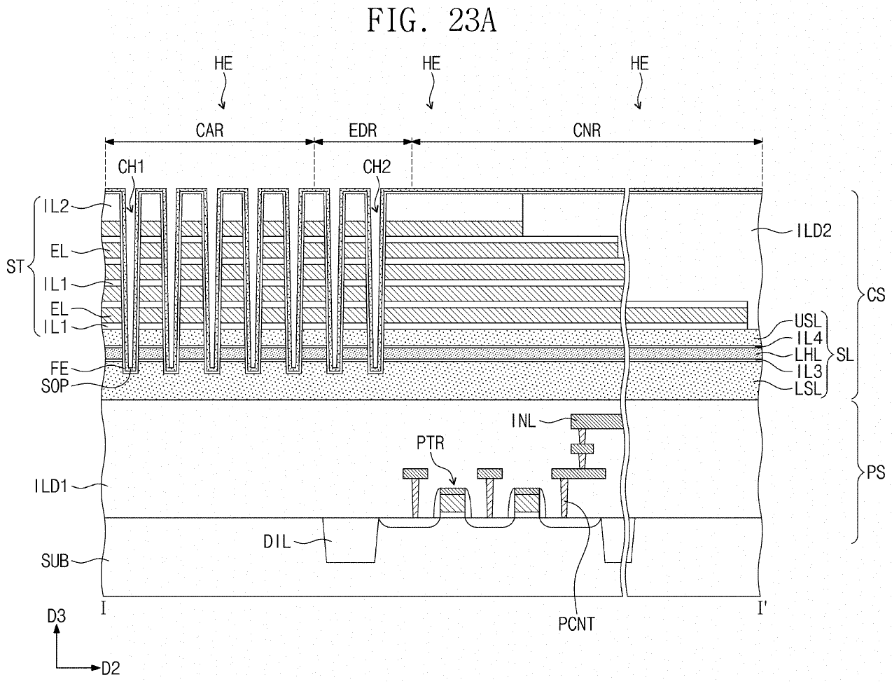

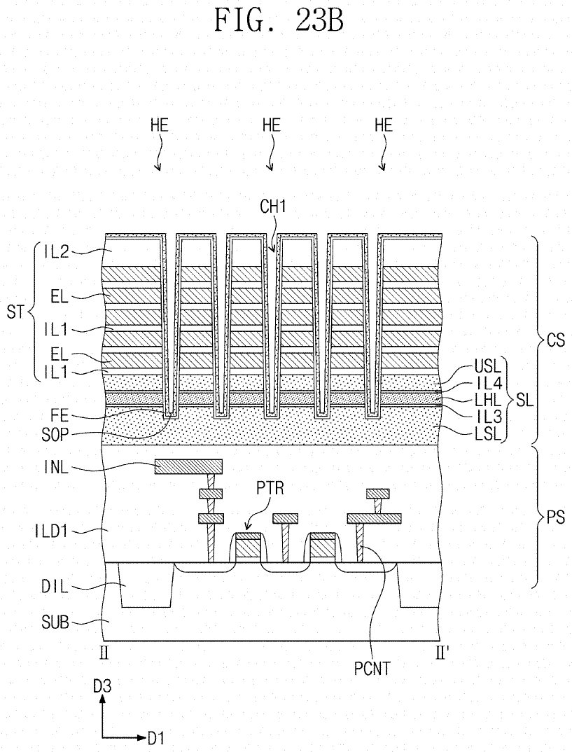

Referring to FIGS. 18, 23A, and 23B, the ferroelectric layer FE may be formed on inner sidewalls of the first and second channel holes CH1 and CH2. For example, the ferroelectric layer FE may include a hafnium (Hf) oxide, and may further include at least one of zirconium (Zr), silicon (Si), aluminum (Al), gadolinium (Gd), or yttrium (Y). The ferroelectric layer FE may be conformally formed using an atomic layer deposition (ALD) process. The ferroelectric layer FE may extend to an upper surface of the second insulation layer IL2 and an upper surface of the second interlayer dielectric ILD2.

The oxide semiconductor layer SOP may be formed on the ferroelectric layer FE. For example, the oxide semiconductor layer SOP may include at least one of In₂O₃, ZnO, IZO, IGO, ZTO, AZO, GZO, IGZO, IZTO, or HIZO. The oxide semiconductor layer SOP may be conformally formed using an atomic layer deposition (ALD) process. The oxide semiconductor layer SOP may extend along the ferroelectric layer FE. The oxide semiconductor layer SOP may vertically extend along inner sidewalls of the first and second channel holes CH1 and CH2. A thermal expansion coefficient of the oxide semiconductor layer SOP may be different from a thermal expansion coefficient of the ferroelectric layer FE. The electron density of the oxide semiconductor layer SOP may be adjusted by temperature of the atomic layer deposition (ALD) process for depositing the oxide semiconductor layer SOP.

An annealing process HE may be performed on the oxide semiconductor layer SOP. The annealing process HE may be performed for about 1 second to about 600 seconds at a temperature of about 280° C. to about 1000° C. Preferably, the annealing process HE may be performed at a temperature of about 400° C. to about 600° C. The ferroelectric phase of the ferroelectric layer FE may be induced by the annealing process HE. In detail, the ferroelectric phase of the ferroelectric layer FE may be induced by performing the annealing process HE on the oxide semiconductor layer SOP. That is, the oxide semiconductor layer SOP may function as a capping layer for inducing the ferroelectric phase.

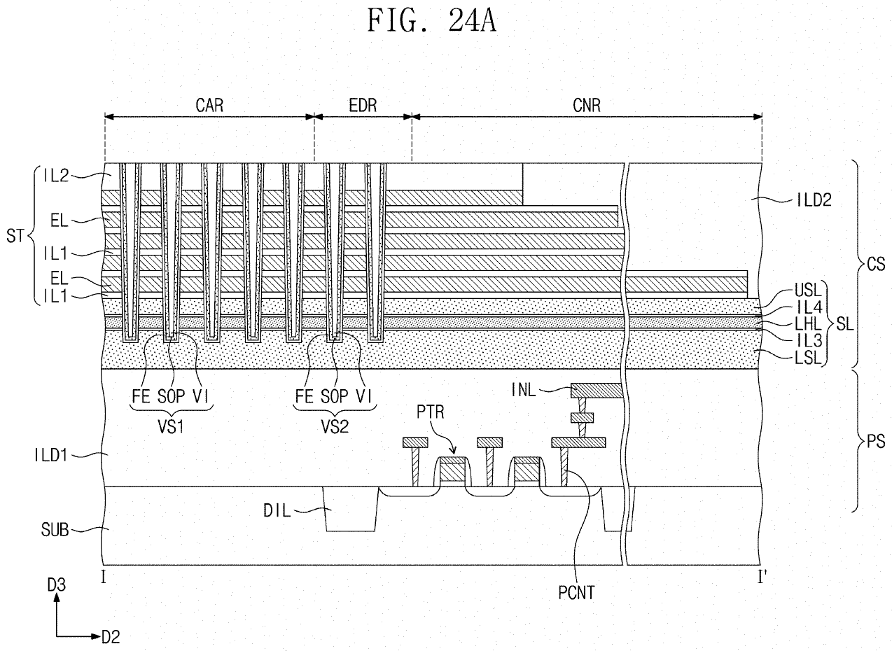

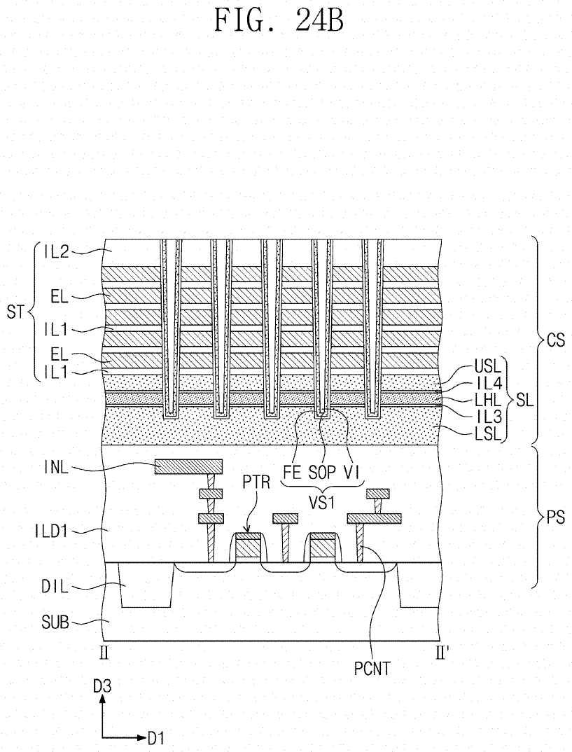

Referring to FIGS. 18, 24A, and 24B, the first and second vertical channel structures VS1 and VS2 may be formed in the first and second channel holes CH1 and CH2, respectively. Forming the first and second vertical channel structures VS1 and VS2 may include forming the pillar VI in a residual portion of the first and second channel holes CH1 and CH2 and performing a planarization process on the pillar VI, the oxide semiconductor layer SOP, and the ferroelectric layer FE. The planarization process may be performed until an upper surface of the second insulation layer IL2 and an upper surface of the second interlayer dielectric ILD2 are exposed. The oxide semiconductor layer SOP may be disposed between the pillar VI and the ferroelectric layer FE without being removed.

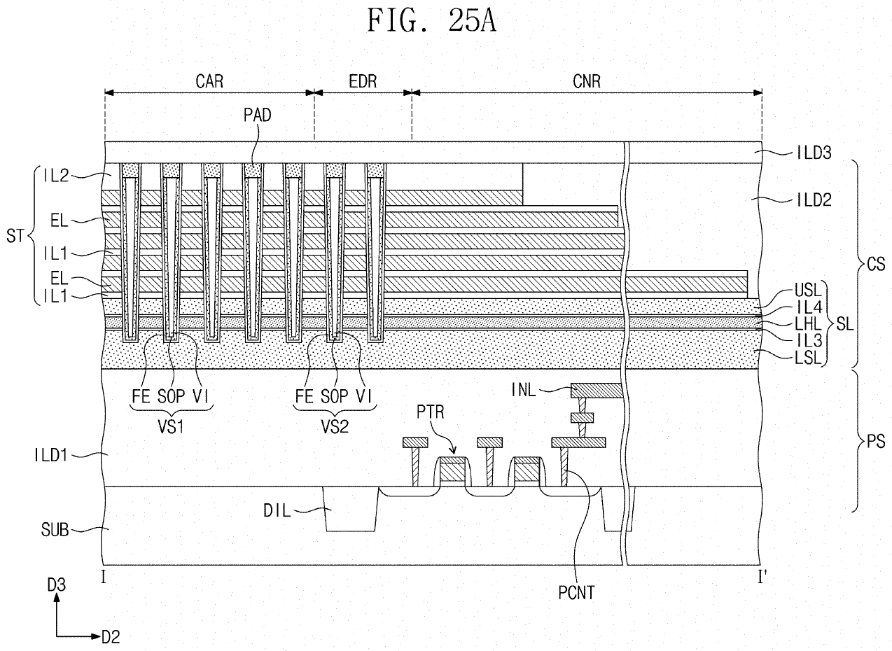

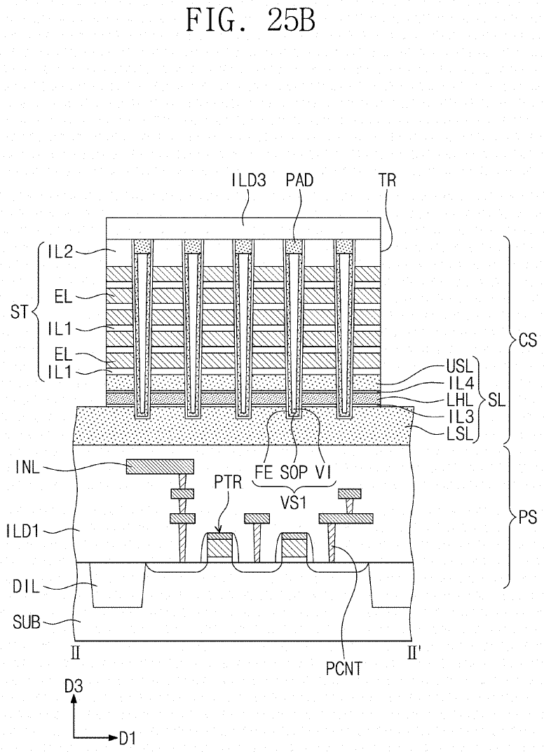

Referring to FIGS. 18, 25A, and 25B, the conductive pad PAD may be formed in each of the first and second vertical channel structures VS1 and VS2. Forming the conductive pad PAD may include forming a recess by removing upper portions of the pillar VI and oxide semiconductor layer SOP and filling the recess with a semiconductor material and/or conductive material. The conductive pad PAD may cover an upper surface of the oxide semiconductor layer SOP and an upper surface of the pillar VI. A sidewall of the conductive pad PAD may contact the ferroelectric layer FE. The conductive pad PAD may include a semiconductor material and/or conductive material doped with impurities. An upper surface of the conductive pad PAD and an upper surface of the ferroelectric layer FE may be substantially coplanar. The ferroelectric layer FE may be disposed between the conductive pad PAD and the electrode structure ST.

The third interlayer dielectric ILD3 may be formed on the electrode structure ST. Trenches TR penetrating the electrode structure ST may be formed by patterning the electrode structure ST. The trenches TR may extend parallel in the second direction D2 (see FIG. 15). The trench TR may expose the lower semiconductor layer LSL. The trench TR may expose sidewalls of the electrodes EL. The trench TR may expose a sidewall of the third insulation layer IL3, a sidewall of the lower sacrificial layer LHL, and a sidewall of the fourth insulation layer IL4.

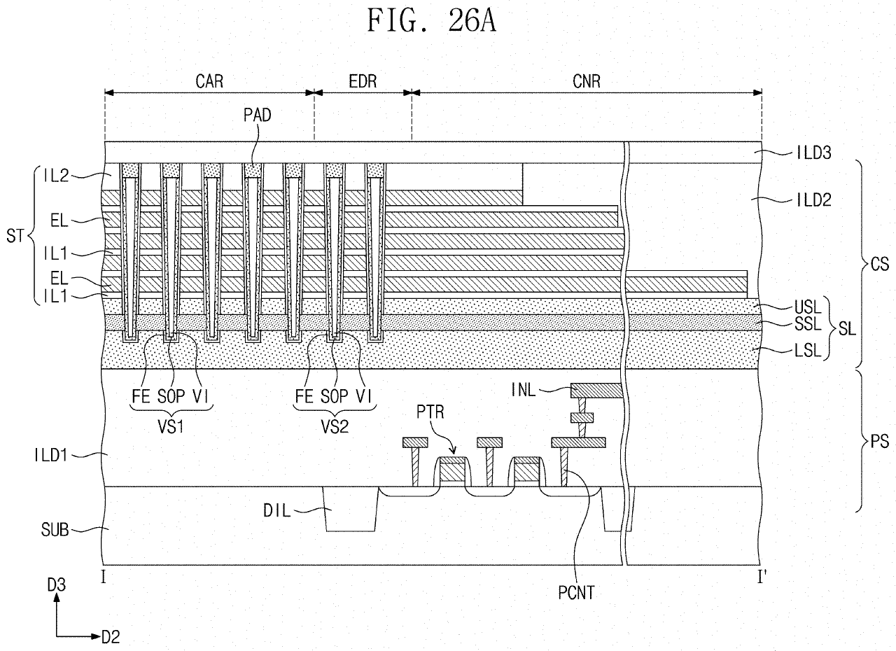

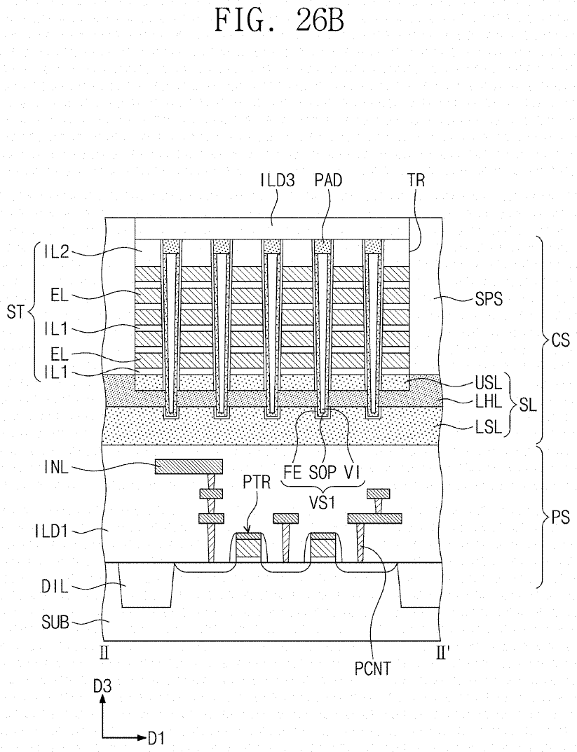

Referring to FIGS. 18, 26A, and 26B, the lower sacrificial layer LHL exposed by the trenches TR may be replaced with the source semiconductor layer SSL. In detail, the lower sacrificial layer LHL exposed by the trenches TR may be selectively removed. As the lower sacrificial layer LHL is removed, a lower portion of the ferroelectric layer FE of each of the first and second vertical channel structures VS1 and VS2 may be exposed.

The exposed lower portion of the ferroelectric layer FE may be selectively removed. Therefore, a lower portion of the oxide semiconductor layer SOP may be exposed. While the lower portion of the ferroelectric layer FE is being removed, the third and fourth insulation layers IL3 and IL4 may be removed together.

The source semiconductor layer SSL may be formed in a space from which the third insulation layer IL3, the lower sacrificial layer LHL, and the fourth insulation layer IL4 have been removed. The source semiconductor layer SSL may directly contact the exposed lower portion of the oxide semiconductor layer SOP. The source semiconductor layer SSL may directly contact the lower semiconductor layer LSL disposed thereunder. The source semiconductor layer SSL may directly contact the upper semiconductor layer USL disposed thereon. The lower semiconductor layer LSL, the source semiconductor layer SSL, and the upper semiconductor layer USL may constitute the second substrate SL.

The separation structures SPS filling the trenches TR may be formed. The separation structures SPS may extend in the second direction D2.

Referring back to FIGS. 18, 19A, and 19B, the bit line contact plugs BPLG may be formed, which penetrate the third interlayer dielectric ILD3 and are connected to the conductive pads PAD respectively. The word line contact plugs WPLG may be formed, which penetrate the third interlayer dielectric ILD3 and are connected to the electrodes EL respectively. The bit lines BL electrically connected to the bit line contact plugs BPLG and the upper wirings UIL electrically connected to the word line contact plugs WPLG may be formed on the third interlayer dielectric ILD3.

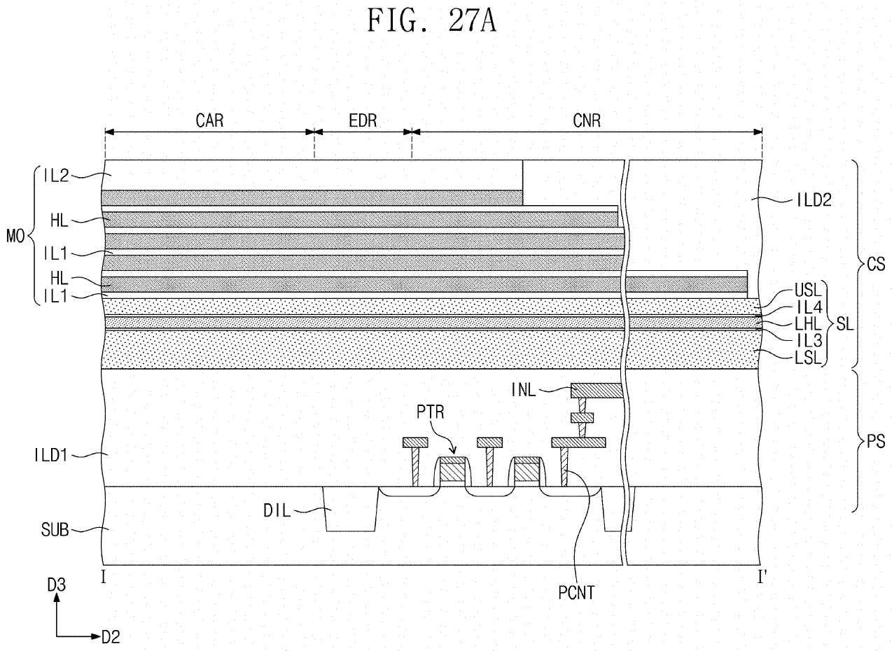

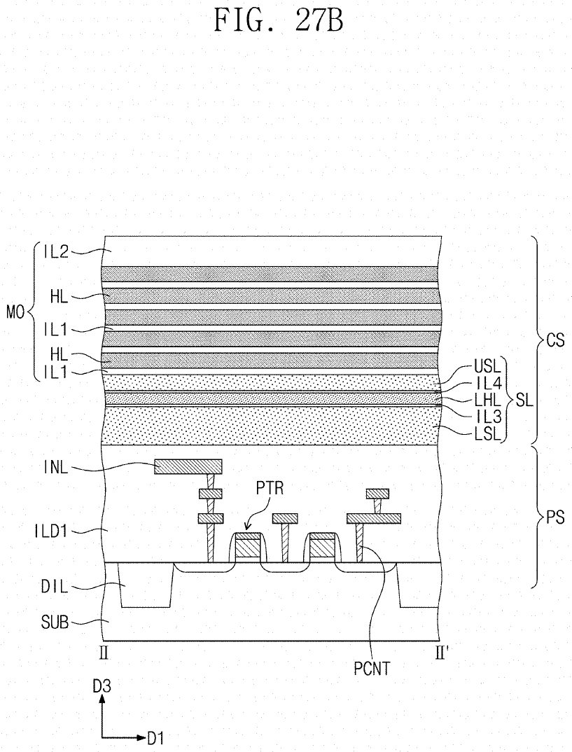

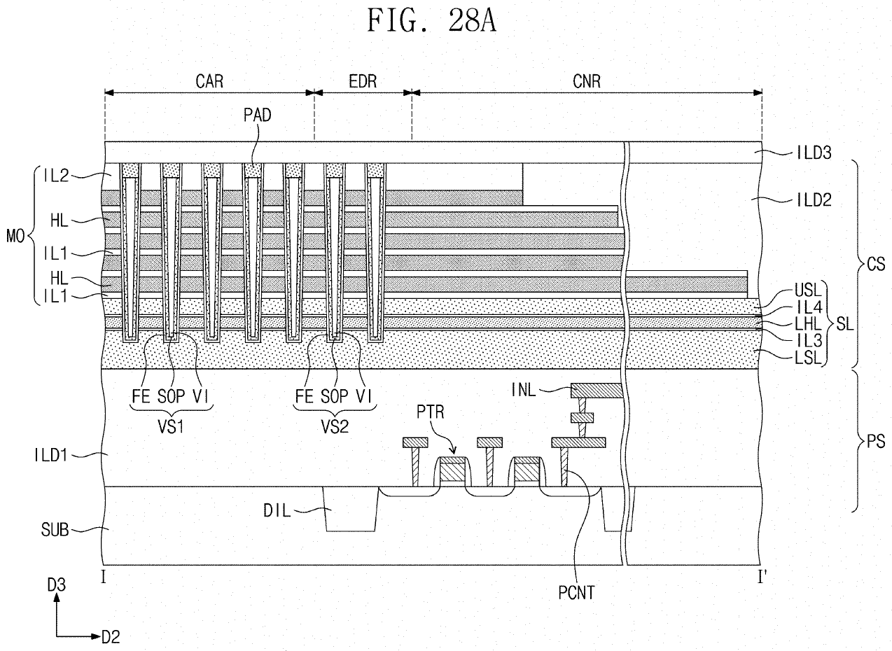

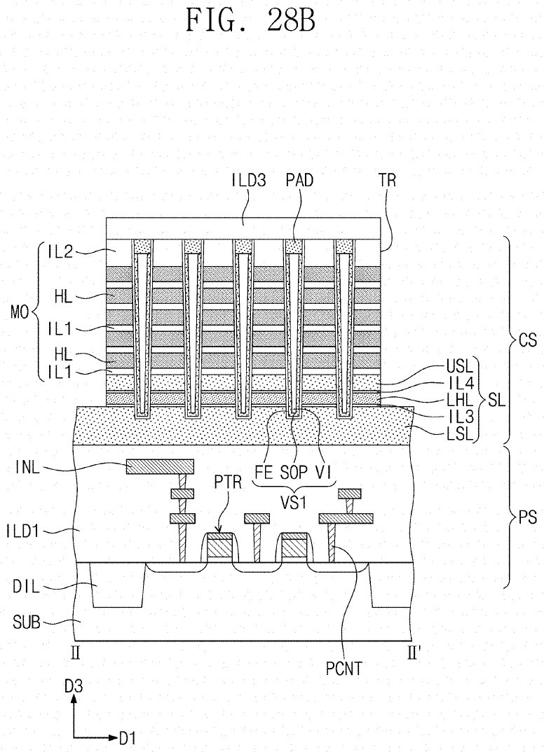

FIGS. 27A and 28A, which are for describing a method for manufacturing a semiconductor memory device according to embodiments of the inventive concept, are cross-sectional views of the semiconductor memory device taken along line I-I′ of FIG. 18. FIGS. 27B and 28B, which are for describing a method for manufacturing a semiconductor memory device according to embodiments of the inventive concept, are cross-sectional views of the semiconductor memory device taken along line II-II′ of FIG. 18. Hereinafter, descriptions overlapping with the above descriptions will not be provided, and differences will be described in detail.

Referring to FIGS. 18, 27A, and 28B, a mold structure MO may be formed on the second substrate SL. In detail, the mold structure MO may be formed by alternately stacking the first insulation layers IL1 and the sacrificial layers HL on the upper semiconductor layer USL. The second insulation layer IL2 may be formed in an uppermost portion of the mold structure MO. The first insulation layers ILL the sacrificial layers HL, and the second insulation layer IL2 may be deposited using thermal chemical vapor deposition (THCVD), plasma enhanced chemical vapor deposition (PECVD), physical vapor deposition (PVD), or atomic layer deposition (ALD). The first insulation layers IL1 and the second insulation layer IL2 may include a silicon oxide film, and the sacrificial layers HL may include a silicon nitride film or silicon oxynitride film.

A stepped structure may be formed in the mold structure MO in the connection region CNR. The second interlayer dielectric ILD2 may be formed on the mold structure MO. Forming the second interlayer dielectric ILD2 may include forming an insulation film covering the mold structure MO and performing a planarization process on the insulation film until the second insulation layer IL2 is exposed. Thereafter, the same processes as described above with reference to FIGS. 18 and 22A to 24B may be performed. Namely, the first and second vertical channel structures VS1 and VS2 penetrating the mold structure MO may be formed.

Referring to FIGS. 18, 28A, and 28B, the conductive pad PAD may be formed in each of the first and second vertical channel structures VS1 and VS2.

The third interlayer dielectric ILD3 may be formed on the mold structure MO. Trenches TR penetrating the mold structure MO may be formed by patterning the mold structure MO. The trenches TR may extend parallel in the second direction D2 (see FIG. 15). The trench TR may expose the lower semiconductor layer LSL. The trench TR may expose sidewalls of the sacrificial layers HL. The trench TR may expose a sidewall of the third insulation layer IL3, a sidewall of the lower sacrificial layer LHL, and a sidewall of the fourth insulation layer IL4.

Referring back to FIGS. 18, 26A, and 26B, the lower sacrificial layer LHL exposed by the trenches TR may be replaced with the source semiconductor layer SSL. Since the sacrificial layers HL exposed by the trenches TR are replaced with the electrodes EL, the electrode structure ST may be formed. In detail, the sacrificial layers HL exposed through the trenches TR may be selectively removed. The electrodes EL may be formed in spaces in which the sacrificial layers HL have been removed. The separation structures SPS filling the trenches TR, respectively, may be formed.

Referring back to FIGS. 18, 19A, and 19B, the word line contact plugs WPLG and the bit line contact plugs WPLG penetrating the third interlayer dielectric ILD3 may be formed.

The bit lines BL and the upper wirings UIL may be formed on the third interlayer dielectric ILD3.

The oxide semiconductor layer of the semiconductor memory device according to embodiments of the inventive concept may function as a channel layer and a capping layer. Accordingly, an additional interfacial layer may not be formed between the oxide semiconductor layer and the ferroelectric layer, and a process of forming the capping layer may be skipped, thus suppressing occurrence of a surface defect in the ferroelectric layer. As a result, electrical characteristics of the semiconductor memory device may be improved, and a manufacturing process may be simplified.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A method for manufacturing a semiconductor memory device, comprising:
forming an electrode structure by alternately stacking insulation layers and electrodes on a substrate;
forming a channel hole penetrating the electrode structure; and
forming a vertical channel structure filling the channel hole,
wherein the forming the vertical channel structure comprises:
forming a ferroelectric layer on an inner sidewall of the channel hole;
forming an oxide semiconductor layer on the ferroelectric layer; and
performing an annealing process on the oxide semiconductor layer.

2. The method of claim 1, wherein the ferroelectric layer is conformally formed using an atomic layer deposition process.

3. The method of claim 1, wherein the forming the oxide semiconductor layer comprises:
exposing a portion of the substrate by removing a portion of the ferroelectric layer; and
conformally forming the oxide semiconductor layer on the ferroelectric layer using an atomic layer deposition process,
wherein the oxide semiconductor layer contacts the exposed portion of the substrate.

4. The method of claim 3, wherein the oxide semiconductor layer contacts an upper surface of the substrate functioning as a source.

5. The method of claim 1, wherein a ferroelectric phase of the ferroelectric layer is induced by the annealing process performed on the oxide semiconductor layer.

6. The method of claim 1, wherein the annealing process is performed for about 1 second to about 600 seconds at a temperature of about 280° C. to about 1000° C.

7. The method of claim 1, wherein the ferroelectric layer comprises a hafnium oxide, and further comprises at least one of zirconium, silicon, aluminum, gadolinium, or yttrium.

8. The method of claim 1, wherein the oxide semiconductor layer comprises at least one of In₂O₃, ZnO, IZO, IGO, ZTO, AZO, GZO, IGZO, IZTO, or HIZO.

9. The method of claim 1, further comprising:
forming a pillar filling a residual portion of the channel hole; and
forming a conductive pad on the pillar.

10. The method of claim 1, wherein the ferroelectric layer and the oxide semiconductor layer physically contact each other.

11. A method for manufacturing a semiconductor memory device, comprising:
forming a ferroelectric layer on an electrode;
forming an oxide semiconductor layer on the ferroelectric layer;
performing an annealing process on the oxide semiconductor layer; and
forming a source electrode and a drain electrode on the oxide semiconductor layer,
wherein the ferroelectric layer and the oxide semiconductor layer physically contact each other.

12. The method of claim 11, wherein a ferroelectric phase of the ferroelectric layer is induced by the annealing process performed on the oxide semiconductor layer.

13. The method of claim 11, wherein the annealing process is performed for about 1 second to about 600 seconds at a temperature of about 280° C. to about 1000° C.

14. The method of claim 11, wherein the oxide semiconductor layer comprises at least one of In₂O₃, ZnO, IZO, IGO, ZTO, AZO, GZO, IGZO, IZTO, or HIZO.

15. A semiconductor memory device comprising:
a substrate;
an electrode structure comprising a plurality of electrodes stacked on the substrate; and
a vertical channel structure penetrating the electrode structure;
wherein the vertical channel structure comprises:
an oxide semiconductor layer extending vertically; and
a ferroelectric layer between the plurality of electrodes and the oxide semiconductor layer,
wherein the ferroelectric layer and the oxide semiconductor layer physically contact each other.

16. The semiconductor memory device of claim 15, wherein a ferroelectric phase of the ferroelectric layer is induced by the oxide semiconductor layer.

17. The semiconductor memory device of claim 15, wherein the ferroelectric layer comprises a hafnium oxide, and further comprises at least one of zirconium, silicon, aluminum, gadolinium, or yttrium.

18. The semiconductor memory device of claim 15, wherein the oxide semiconductor layer comprises at least one of In₂O₃, ZnO, IZO, IGO, ZTO, AZO, GZO, IGZO, IZTO, or HIZO.

19. The semiconductor memory device of claim 15, wherein the oxide semiconductor layer contacts a source semiconductor layer of the substrate.

20. The semiconductor memory device of claim 15, wherein the oxide semiconductor layer has an electron density of about 10¹⁵ cm⁻³ to about 10²¹ cm⁻¹.
